(19) United States
(12) Patent Application Publication
(10) Pub. No.: US 2026/0079518 A1
(43) Pub. Date: Mar. 19, 2026

(54) SEMICONDUCTOR DEVICE

(71) Applicant: ROHM CO., LTD., Kyoto (JP)

(72) Inventors: Akihiro OGAWA, Kyoto (JP); Shun FUKUSHIMA, Kyoto (JP)

(21) Appl. No.: 19/324,291

(22) Filed: Sep. 10, 2025

(30) Foreign Application Priority Data
Sep. 17, 2024 (JP) 2024-160373

(51) Int. Cl. G05F 3/26; G05F 1/46; G05F 1/575; H03F 1/30

(52) U.S. Cl. CPC G05F 3/262; G05F 1/468; G05F 1/575; H03F 1/301

(57) ABSTRACT

A semiconductor device includes a constant current circuit configured to generate a constant current, and an operating circuit configured to perform an operation associated with a fixed voltage at a first end of a set resistor and a voltage at a second end of the set resistor through which a current corresponding to the constant current flows. The voltage at the second end of the set resistor is a voltage corresponding to the current flowing through the set resistor, and different operations of the operating circuit are associated with different fixed voltages at the first end of the set resistor.

### CROSS-REFERENCE TO RELATED APPLICATION

The present invention claims priority under 35 U.S.C. § 119 to Japanese Patent Application No. 2024-160373, filed on Sep. 17, 2024, the entire contents of which are incorporated herein by reference.

### TECHNICAL FIELD

The present disclosure relates to a semiconductor device.

### BACKGROUND

In the related art, it is known to use an external resistor to determine an operation of a semiconductor device. For example, in the related art, there is disclosed an LED driver that generates an output voltage according to the number of switching pulses. In the technique disclosed in the related art, an internal voltage is divided by two external resistors, a number of switching pulses according to the divided voltage is generated, and an output voltage according to the number of switching pulses is generated. Therefore, the output voltage may be changed by changing the resistance values of the external resistors.

### BRIEF DESCRIPTION OF DRAWINGS

The accompanying drawings, which are incorporated in and constitute a part of the specification, illustrate embodiments of the present disclosure.

FIG. 1 is a block diagram of a system according to a first embodiment.

FIG. 2 is a diagram for explaining an example of an operation of a semiconductor device when a fixed voltage at one end of a set resistor is a ground voltage.

FIG. 3 is a diagram for explaining an example of the operation of the semiconductor device when the fixed voltage at the one end of the set resistor is a power supply voltage.

FIG. 4 is a diagram showing a relationship between a terminal voltage and a resistance value of the set resistor.

FIG. 5 is a diagram showing a table in which set values are associated with set resistor types and terminal voltages.

FIG. 6 is a flowchart showing an example of the operation of the semiconductor device according to the first embodiment.

FIG. 7 is a flowchart showing an example of a process of specifying the fixed voltage according to the first embodiment.

FIG. 8 is a flowchart showing an example of a process of specifying the terminal voltage according to the first embodiment.

FIG. 9 is a flowchart showing an example of a process of controlling a DC/DC converter according to the first embodiment.

FIG. 10 is a block diagram of a system according to a second embodiment.

FIG. 11 is a diagram for explaining operating ranges of a first comparator and a second comparator.

FIG. 12 is a flowchart showing an example of an operation of a semiconductor device according to the second embodiment.

FIG. 13 is a flowchart showing an example of a fixed voltage specifying process and a process of determining a comparator according to the second embodiment.

FIG. 14 is a block diagram of a system according to a third embodiment.

FIG. 15 is a block diagram of a system according to a fourth embodiment.

FIG. 16 is a diagram showing a relationship between a resistance value of a set resistor, a type of the set resistor, a constant current, and a terminal voltage according to the fourth embodiment.

FIG. 17 is a diagram showing a table in which set values are associated with current values of a constant current and terminal voltages in a pull-down type.

FIG. 18 is a flowchart showing an example of an operation of a semiconductor device according to the fourth embodiment.

FIG. 19 is a flowchart showing an example of a constant current determining process according to the fourth embodiment.

FIG. 20 is a flowchart showing an example of a process of controlling a DC/DC converter according to the fourth embodiment.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### Overview

The overview of some exemplary embodiments of the present disclosure will be described. This overview presents, in a simplified form, some concepts of one or more embodiments, as a prologue to the detailed description which will be presented later, and for the purpose of basic understanding of the embodiments, but it is not intended to limit the scope of the invention or the disclosure. This overview is not a comprehensive overview of all possible embodiments, and it is intended to neither identify key elements of all embodiments nor delineate the scope of some or all aspects. For the sake of convenience, “an embodiment” may be used to refer to one embodiment (example or modification) or a plurality of embodiments.

A semiconductor device according to one embodiment includes a constant current circuit configured to generate a constant current, and an operating circuit configured to perform an operation associated with a fixed voltage at a first end of a set resistor and a voltage at a second end of the set resistor through which a current corresponding to the constant current flows. The voltage at the second end of the set resistor is a voltage corresponding to the current flowing through the set resistor. Different operations of the operating circuit are associated with different fixed voltages at the first end of the set resistor.

With this configuration, it is possible to switch the operation to be performed by the operating circuit by switching the fixed voltage at the first end of the set resistor. Thus, the semiconductor device may perform a variety of operations using the operating circuit, as compared to when using a single fixed voltage.

In one embodiment, voltages at second ends of a plurality of set resistors having different magnitudes may be associated with the different fixed voltages at the first end of the set resistor. Different operations of the operating circuit may be associated with the voltages at the second ends of the plurality of set resistors associated with the fixed voltage at the first end of the set resistor.

In one embodiment, the semiconductor device may further include a direction control circuit configured to control a direction of the current flowing through the set resistor, that corresponds to the constant current. The fixed voltage at the first end of the set resistor may be a first fixed voltage or a second fixed voltage larger than the first fixed voltage. The direction control circuit may direct the current flowing through the set resistor from the second end to the first end of the set resistor when the fixed voltage at the first end of the set resistor is the first fixed voltage, and may direct the current flowing through the set resistor from the first end to the second end of the set resistor when the fixed voltage at the first end of the set resistor is the second fixed voltage.

In one embodiment, the semiconductor device may further include a reference voltage circuit configured to generate a reference voltage and to be capable of switching a magnitude of the reference voltage, a comparison circuit including a comparator configured to compare the reference voltage with the voltage at the second end of the set resistor, and a control circuit configured to control the operation of the operating circuit. The control circuit may determine the operation to be performed by the operating circuit based on a comparison result obtained by the comparator.

In one embodiment, the control circuit may specify the fixed voltage at the first end of the set resistor based on a comparison result obtained by the comparator when no current flows through the set resistor, specify the voltage at the second end of the set resistor based on a comparison result obtained by the comparator when the current corresponding to the constant current flows through the set resistor, and cause the operating circuit to perform an operation associated with the specified fixed voltage at the first end of the set resistor and the specified voltage at the second end of the set resistor.

In one embodiment, the reference voltage circuit may sequentially switch the magnitude of the reference voltage based on the comparison result obtained by the comparator. The control circuit may specify the voltage at the second end of the set resistor based on the comparison result obtained by the comparator, which corresponds to the sequential switching of the magnitude of the reference voltage, and cause the operating circuit to perform an operation associated with the specified voltage at the second end of the set resistor.

In one embodiment, the reference voltage circuit may generate the reference voltage by dividing a voltage difference between the first fixed voltage and the second fixed voltage, and switch the magnitude of the reference voltage by switching a voltage division ratio.

In one embodiment, the comparison circuit may include a first comparator configured to operate normally when an input voltage falls within a first voltage range, and a second comparator configured to operate normally when the input voltage falls within a second voltage range. A lower limit voltage in the first voltage range may be equal to or smaller than the first fixed voltage. An upper limit voltage in the first voltage range may be smaller than the second fixed voltage. A lower limit voltage in the second voltage range may be larger than the first fixed voltage. An upper limit voltage in the second voltage range may be equal to or larger than the second fixed voltage. Each of the first comparator and the second comparator may compare the reference voltage with the voltage at the second end of the set resistor. The control circuit may specify the voltage at the second end of the set resistor based on a comparison result obtained by the first comparator when the fixed voltage at the first end of the set resistor is the first fixed voltage, specify the voltage at the second end of the set resistor based on a comparison result obtained by the second comparator when the fixed voltage at the first end of the set resistor is the second fixed voltage, and cause the operating circuit to perform an operation associated with the specified voltage at the second end of the set resistor.

In one embodiment, the semiconductor device may further include a first current mirror circuit configured to copy the constant current. The direction control circuit may include a second current mirror circuit configured to copy a current generated by the first current mirror circuit copying the constant current, and a switching circuit configured to be capable of switching the current flowing through the set resistor between the current generated by the first current mirror circuit and a current generated by the second current mirror circuit. The switching circuit may direct the current flowing through the set resistor from the second end to the first end of the set resistor by passing the current generated by the first current mirror circuit configured to copy the constant current through the set resistor, and direct the current flowing through the set resistor from the first end to the second end of the set resistor by passing the current generated by the second current mirror circuit configured to copy the current generated by the first current mirror circuit through the set resistor.

In one embodiment, the first fixed voltage may be a ground voltage. The second fixed voltage may be a power supply voltage. The first current mirror circuit may be composed of two P-channel MOS transistors. Sources of the two P-channel MOS transistors may be connected to an application terminal of the power supply voltage.

In one embodiment, the constant current circuit may include a voltage divider circuit configured to divide the power supply voltage, an operational amplifier, a MOS transistor, and a resistor provided between the MOS transistor and a ground. The MOS transistor may be provided so as to receive an output signal of the operational amplifier at a gate of the MOS transistor and allow the constant current to flow through the MOS transistor. A voltage generated by the voltage divider circuit configured to divide the power supply voltage may be input to a non-inverting input terminal of the operational amplifier. The voltage at the first end of the set resistor on a side of the MOS transistor may be input to an inverting input terminal of the operational amplifier.

In one embodiment, the semiconductor device may further include an A/D converter configured to convert the voltage at the second end of the set resistor into a digital signal, and a control circuit configured to determine an operation to be performed by the operating circuit based on the digital signal. The control circuit may specify the fixed voltage at the first end of the set resistor based on the digital signal when no current flows through the set resistor, specify the voltage at the second end of the set resistor based on the digital signal when the current corresponding to the constant current flows through the set resistor, and cause the operating circuit to perform an operation associated with the specified voltage at the second end of the set resistor.

In one embodiment, the constant current circuit may be configured to be capable of switching a magnitude of the constant current. The operating circuit may perform an operation associated with the constant current generated by the constant current circuit in addition to the fixed voltage at the first end of the set resistor and the voltage at the second end of the set resistor through which the current corresponding to the constant current flows. Different operations of the operating circuit may be associated with constant currents of different magnitudes, which are generated by the constant current circuit.

In one embodiment, voltages at second ends of a plurality of set resistors having different magnitudes may be associated with the constant current generated by the constant current circuit. Different operations may be associated with the voltages at the second ends of the plurality of set resistors associated with the constant current.

In one embodiment, the semiconductor device may further include a control circuit configured to control the operation of the operating circuit. The constant current circuit may switch the magnitude of the constant current so that the voltage at the first end of the set resistor falls within a range of a voltage to be generated at the second end of the set resistor when the voltage at the first end of the set resistor falls outside the range of the voltage to be generated. The control circuit may determine the operation to be performed by the operating circuit based on the constant current generated by the constant current circuit and the voltage at the second end of the set resistor when the voltage at the second end of the set resistor falls within the range of the voltage to be generated. The operating circuit may perform the operation determined by the control circuit.

In one embodiment, the semiconductor device may further include a reference voltage circuit configured to generate a reference voltage and to be capable of switching the magnitude of the reference voltage, and a comparator configured to compare the reference voltage with the voltage at the second end of the set resistor. The control circuit may determine the operation to be performed by the operating circuit based on a comparison result obtained by the comparator.

In one embodiment, the reference voltage circuit may generate an upper limit or lower limit voltage in the range of the voltage to be generated, as the reference voltage. The constant current circuit may switch the magnitude of the constant current so that the voltage at the first end of the set resistor falls within the range of the voltage to be generated, when the voltage at the second end of the set resistor falls outside the range of the voltage to be generated, based on the comparison result obtained by the comparator when the upper or lower limit reference voltage is generated.

In one embodiment, the constant current circuit may switch the magnitude of the constant current based on the comparison result obtained by the comparator so that the voltage at the second end of the set resistor falls within the range of the voltage to be generated. The reference voltage circuit may sequentially switch the magnitude of the reference voltage based on the comparison result obtained by the comparator. The control circuit may specify the voltage at the second end of the set resistor based on the comparison result obtained by the comparator in response to the sequential switching of the magnitude of the reference voltage, and cause the operating circuit to perform an operation associated with the specified voltage at the second end of the set resistor.

In one embodiment, the constant current circuit may switch the magnitude of the constant current based on the comparison result obtained by the comparator so that the voltage at the second end of the set resistor falls within the range of the voltage to be generated, with the reference voltage fixed to the upper or lower limit voltage. The reference voltage circuit may sequentially switch the magnitude of the reference voltage after switching the magnitude of the constant current so that the voltage at the second end of the set resistor falls within the range of the voltage to be generated. The control circuit may specify the voltage at the second end of the set resistor based on the comparison result obtained by the comparator in response to the sequential switching of the magnitude of the reference voltage, and cause the operating circuit to perform an operation associated with the specified voltage at the second end of the set resistor.

In one embodiment, the reference voltage circuit may generate the reference voltage by dividing a power supply voltage, and switches the magnitude of the reference voltage by switching a voltage division ratio.

In one embodiment, the semiconductor device may further include an A/D converter configured to convert the voltage at the second end of the set resistor into a digital signal. The control circuit may determine an operation to be performed by the operating circuit based on the digital signal.

In one embodiment, the constant current circuit may switch the magnitude of the constant current based on the digital signal generated by the A/D converter so that the voltage at the second end of the set resistor falls within the range of the voltage to be generated. The control circuit may specify the voltage at the second end of the set resistor based on the digital signal generated by the A/D converter, with the magnitude of the constant current fixed so that the voltage at the second end of the set resistor falls within the range of the voltage to be generated, and cause the operating circuit to perform an operation associated with the specified voltage at the second end of the set resistor.

In one embodiment, the constant current circuit may generate a first constant current when the resistance value of the set resistor is a first resistance value, and generates a second constant current having a magnitude of 1/N times the first constant current when the resistance value of the set resistor is a second resistance value that is N times the first resistance value (N is a number larger than 1).

In one embodiment, the semiconductor device may further include a current mirror circuit configured to copy the constant current generated by the constant current circuit. A current corresponding to the constant current copied by the current mirror circuit may flow through the set resistor.

In one embodiment, the operating circuit may be a DC/DC converter.

### EMBODIMENTS

Preferred embodiments will now be described with reference to the drawings. Like or equivalent components, members, and processes illustrated in each drawing are given like reference numerals and a repeated description thereof will be properly omitted. Further, the embodiments are presented by way of example only and are not intended to limit the present disclosure and invention, and any features or combination thereof described in the embodiments may not necessarily be essential to the present disclosure and invention.

In the present disclosure, “a state where a member A is connected to a member B” includes not only a case where the member A and the member B are physically directly connected, but also a case where the member A and the member B are indirectly connected through any other member that does not substantially affect an electrical connection state between the members A and B or does not impair functions and effects achieved by combinations of the members A and B.

Similarly, “a state where a member C is connected (installed) between a member A and a member B” includes to not only a case where the member A and the member C or the member B and the member C are directly connected, but also a case where the member A and the member C or the member B and the member C are indirectly connected through any other member that does not substantially affect an electrical connection state between the members A and C or the members B and C or does not impair functions and effects achieved by combinations of the members A and C or the members B and C.

Further, in the present disclosure, symbols attached to electrical signals such as voltage signals and current signals, or circuit elements such as resistors, capacitors, and inductors, represent respective voltage values, current values, or circuit constants (resistance, capacitance, and inductance) as necessary.

Further, in the present disclosure, “integrated” includes a case where all of the components of a circuit are formed on a semiconductor substrate and a case where the main components of a circuit are integrated, and some resistors, capacitors, or the like may be provided outside the semiconductor substrate for adjusting circuit constants.

### First Embodiment

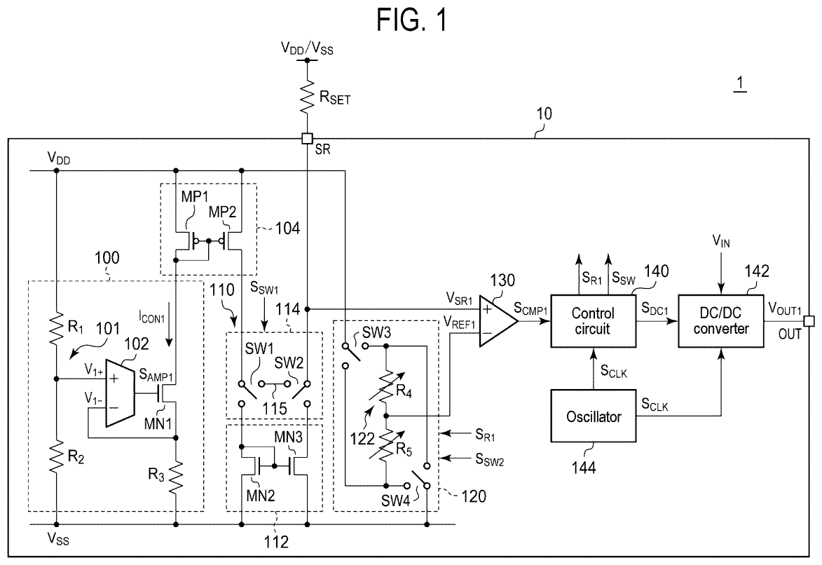

FIG. 1 is a block diagram of a system 1 according to a first embodiment. The system 1 according to this embodiment includes a semiconductor device 10 and an external set resistor R_{SET}. The semiconductor device 10 according to this embodiment may be configured as a PMIC (Power Management Integrated Circuit). Specifically, the semiconductor device 10 may have a plurality of power supply circuits (not shown).

The semiconductor device 10 includes a constant current circuit 100, a first current mirror circuit 104, a direction control circuit 110, a reference voltage circuit 120, a comparator 130, a control circuit 140, a DC/DC converter 142, an oscillator 144, a setting terminal SR, and an output terminal OUT. The semiconductor device 10 executes an operation according to a set value corresponding to a resistance value of the set resistor R_{SET}, and outputs an output voltage V_{OUT1} from the output terminal OUT.

A fixed voltage at one end of the set resistor R_{SET} according to this embodiment is a first fixed voltage or a second fixed voltage larger than the first fixed voltage. Specifically, the fixed voltage at one end of the set resistor R_{SET} is a ground voltage (V_{SS}) which is the first fixed voltage, or a power supply voltage V_{DD} which is the second fixed voltage. The fixed voltage is a voltage that does not change depending on a current flowing through the set resistor R_{SET}. The other end of the set resistor R_{SET} is connected to the setting terminal SR.

The set resistor R_{SET} may be replaced with a new one, and the resistance value of the set resistor R_{SET} may be changed by replacing the set resistor R_{SET}. The fixed voltage at one end of the set resistor R_{SET} may be switched between the power supply voltage V_{DD} and the ground voltage. Therefore, the set resistor R_{SET} may be switched between a pull-up resistor and a pull-down resistor.

The constant current circuit 100 generates a constant current I_{CON1}. The constant current circuit 100 includes a voltage divider circuit 101, an operational amplifier 102, a transistor MN1, and a resistor R₃.

The voltage divider circuit 101 divides the power supply voltage V_{DD}. A voltage V₁₊ generated by the voltage divider circuit 101 configured to divide the power supply voltage V_{DD} is input to a non-inverting input terminal of the operational amplifier 102. The voltage divider circuit 101 according to this embodiment includes two resistors R₁ and R₂ connected in series.

One end of the resistor R₁ is connected to an application terminal of the power supply voltage V_{DD}, and the other end of the resistor R₁ is connected to the non-inverting input terminal of the operational amplifier 102. One end of the resistor R₂ is connected to the non-inverting input terminal of the operational amplifier 102, and the other end of the resistor R₂ is connected to an application terminal of the ground voltage (also referred to as “ground”). The voltage V₁₊ generated by dividing the power supply voltage V_{DD} is expressed by Equation (1) below.

$${V}_{1 +} = {V}_{D D} \times {R}_{2} / ( {R}_{1} + {R}_{2} ) \qquad ( 1 )$$

The transistor MN1 is composed of a MOS (Metal Oxide Semiconductor) transistor. The transistor MN1 according to this embodiment is an N-channel MOS transistor. The transistor MN1 according to this embodiment is provided so that its gate receives an output signal S_{AMP1} of the operational amplifier 102 and the constant current I_{CON1} flows through the transistor MN1.

The resistor R₃ is provided between the transistor MN1 and the ground. Specifically, one end of the resistor R₃ is connected to the source of the transistor MN1, and the other end of the resistor R₃ is connected to the ground. When the constant current I_{CON1} flows through the resistor R₃, a voltage V₁₋ is generated at one end of the resistor R₃ on the transistor MN1 side. The voltage V₁₋ is expressed by Equation (2) below.

$${V}_{1 -} = {R}_{3} \times {I}_{CON 1} \qquad ( 2 )$$

The voltage V₁₋ is input to an inverting input terminal of the operational amplifier 102.

The operational amplifier 102 generates the output voltage S_{AMP1} so that the voltage V₁₊ input to the non-inverting input terminal and the voltage V₁₋ input to the inverting input terminal are the same (V₁₊=V₁₋). Therefore, the constant current I_{CON1} is expressed by Equation (3) below from Equations (1) and (2).

$${I}_{CON 1} = {V}_{D D} \times {R}_{2} / \{ {R}_{3} \times ( {R}_{1} + {R}_{2} ) \} \qquad ( 3 )$$

The first current mirror circuit 104 copies the constant current I_{CON1} generated by the constant current circuit 100. The first current mirror circuit 104 according to this embodiment includes two transistors MP1 and MP2. Each of the two transistors MP1 and MP2 is a P-channel MOS transistor. The transistor MP1 is an input-side transistor, and the transistor MP2 is an output-side transistor.

An application terminal of the power supply voltage V_{DD} is connected to sources of the transistors MP1 and MP2. A gate of the transistor MP1 is connected to a drain of the transistor MP1 in common with a gate of the transistor MP2. A drain of the transistor MP1 is connected to a drain of the transistor MN1.

The direction control circuit 110 controls the direction of a current according to the constant current I_{CON1} flowing through the set resistor R_{SET}. Specifically, when the fixed voltage at one end of the set resistor R_{SET} is the ground voltage, the direction control circuit 110 directs the current flowing through the set resistor R_{SET} from the other end to one end of the set resistor R_{SET}. In addition, when the fixed voltage at one end of the set resistor R_{SET} is the power supply voltage V_{DD}, the direction control circuit 110 directs the current flowing through the set resistor R_{SET} from one end to the other end of the set resistor R_{SET}.

The direction control circuit 110 according to this embodiment includes a second current mirror circuit 112 and a switching circuit 114.

The second current mirror circuit 112 copies a current generated by the first current mirror circuit 104 by copying the constant current I_{CON1}. The second current mirror circuit 112 according to this embodiment includes two transistors MN2 and MN3. Each of the two transistors MN2 and MN3 is configured as an N-channel MOS transistor. The transistor MN2 is an input-side transistor, and the transistor MN3 is an output-side transistor. Sources of the transistors MN2 and MN3 are connected to the ground. A gate of the transistor MN2 is connected to a drain of the transistor MN2 in common with a gate of the transistor MN3.

The switching circuit 114 is configured to be capable of switching between a current generated by the first current mirror circuit 104 configured to copy the current flowing through the set resistor R_{SET} and a current generated by the second current mirror circuit 112 configured to copy the current generated by the first current mirror circuit 104. The switching circuit 114 may direct the current flowing through the set resistor R_{SET} from the other end to one end of the set resistor R_{SET} by passing the current generated by the first current mirror circuit 104 copying the current flowing through the set resistor R_{SET} through the set resistor R_{SET}. Further, the switching circuit 114 may direct the current flowing through the set resistor R_{SET} from one end to the other end of the set resistor R_{SET} by passing the current generated by the second current mirror circuit 112 copying the current generated by the first current mirror circuit 104 through the set resistor R_{SET}.

The switching circuit 114 according to this embodiment includes a first switch SW1, a second switch SW2, and a common line 115. The first switch SW1 may switch the connection destination of the drain of the transistor MP2 between the common line 115 and the drain of the transistor MN2. The first switch SW1 may also open the drain of the transistor MP2. The second switch SW2 may switch the connection destination of the setting terminal SR between the common line 115 and the drain of the transistor MN3. The second switch SW2 may also open the setting terminal SR.

The reference voltage circuit 120 generates a reference voltage V_{REF1} and is configured to be capable of switching the magnitude of the reference voltage V_{REF1}. The reference voltage circuit 120 generates the reference voltage V_{REF1} by dividing a difference between the first fixed voltage and the second fixed voltage. In this embodiment, the reference voltage circuit 120 generates the reference voltage V_{REF1} by dividing the power supply voltage V_{DD}. The reference voltage V_{REF1} is input to the inverting input terminal of the comparator 130.

The reference voltage circuit 120 includes two resistors R₄ and R₅ connected in series, a third switch SW3, and a fourth switch SW4. The two resistors R₄ and R₅ are each a variable resistor. The third switch SW3 is provided so that the application terminal of the power supply voltage V_{DD} may be connected to one of one end of the resistor R₄ opposite the resistor R₅ and one end of the resistor R₅ opposite the resistor R₄. The fourth switch SW4 is provided so that one of the one end of the resistor R₄ opposite the resistor R₅ and the one end of the resistor R₅ opposite the resistor R₄ may be connected to the ground.

The reference voltage circuit 120 switches a magnitude of the reference voltage V_{REF1} by switching a voltage division ratio. Specifically, the magnitude of the reference voltage V_{REF1} is switched by switching the resistance values of the resistors R₄ and R₅.

The comparator 130 may be configured, for example, as a rail-to-rail comparator. The comparator 130 constitutes a comparison circuit. The comparator 130 compares the reference voltage V_{REF1} with a terminal voltage V_{SR1} to generate a comparison signal S_{CMP1} indicating the comparison result. The comparison signal S_{CMP1} is a high-level signal when the terminal voltage V_{SR1} is larger than the reference voltage V_{REF1}, and is a low-level signal when the terminal voltage V_{SR1} is smaller than the reference voltage V_{REF1}. The comparison signal S_{CMP1} is input to the control circuit 140.

The control circuit 140 may be configured with combinations of various logic circuits. The control circuit 140 comprehensively controls the operation of the semiconductor device 10. For example, the control circuit 140 controls the operation of the DC/DC converter 142. Specifically, the control circuit 140 causes the DC/DC converter 142 to perform an operation associated with the fixed voltage at one end of the set resistor R_{SET} and the voltage (terminal voltage V_{SR1}) at the other end of the set resistor R_{SET} through which a current corresponding to the constant current I_{CON1} flows. Different fixed voltages at one end of the set resistor R_{SET} are associated with different operations of the DC/DC converter 142.

The control circuit 140 according to this embodiment determines the operation to be performed by the DC/DC converter 142 based on the comparison result obtained by the comparator 130. Specifically, the control circuit 140 determines the operation associated with the fixed voltage at one end of the set resistor R_{SET} and the terminal voltage V_{SR1} based on the comparison signal S_{CMP1}, and generates a control signal S_{DC1} for causing the DC/DC converter 142 to perform the determined operation.

The control circuit 140 according to this embodiment may generate a signal S_{SW} for switching a switch. The signal S_{SW} includes a signal S_{SW1} for switching the first switch SW1 and the second switch SW2, and a signal S_{SW2} for switching the third switch SW3 and the fourth switch SW4. The control circuit 140 may generate a signal S_{R1} for switching the resistance values of the resistors R₄ and R₅ of the reference voltage circuit 120.

The DC/DC converter 142 generates an output voltage V_{OUT1} according to an input voltage V_{IN}. The DC/DC converter 142 performs the operation associated with the fixed voltage at one end of the set resistor R_{SET} and the voltage (terminal voltage V_{SR1}) at the other end of the set resistor R_{SET} through which a current according to the constant current I_{CON1} flows. In this embodiment, the DC/DC converter 142 performs the operation determined by the control circuit 140.

The oscillator 144 generates a clock signal S_{CLK}. The clock signal S_{CLK} is transmitted to the control circuit 140 and the DC/DC converter 142, and the control circuit 140 and the DC/DC converter 142 each operate in response to the clock signal S_{CLK}.

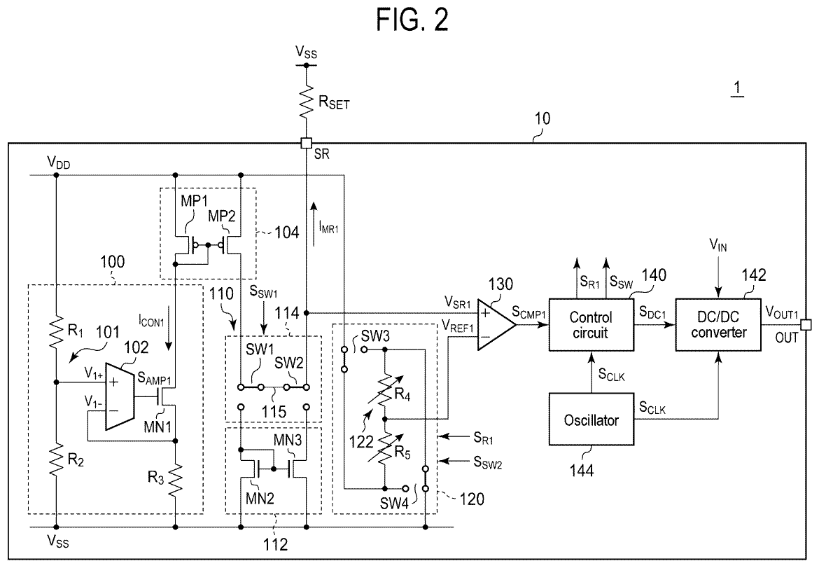

FIG. 2 is a diagram for explaining an example of an operation of the semiconductor device 10 when the fixed voltage at one end of the set resistor R_{SET} is the ground voltage. As shown in FIG. 2, one end of the set resistor R_{SET} is connected to the ground. Therefore, the set resistor R_{SET} is a pull-down resistor.

When the set resistor R_{SET} is the pull-down resistor, the switching circuit 114 may be set to a pull-down type. Specifically, the first switch SW1 connects the drain of the transistor MP2 to the common line 115, and the second switch SW2 connects the setting terminal SR to the common line 115.

A current I_{MR1} generated by the first current mirror circuit 104 by copying the constant current I_{CON1} flows through the set resistor R_{SET} via the common line 115. At this time, the voltage V_{SR1} is generated at the setting terminal SR according to the current I_{MR1}, and is expressed by Equation (4) below.

$${V}_{SR 1} = {R}_{S E T} \times {I}_{MR 1} \qquad ( 4 )$$

When the set resistor R_{SET} is the pull-down resistor, the reference voltage circuit 120 may be set to a pull-down type. Specifically, the third switch SW3 connects the application terminal of the power supply voltage V_{DD} to one end of the resistor R₅ opposite the resistor R₄, and the fourth switch SW4 connects one end of the resistor R₄ opposite the resistor R₅ to the ground. The reference voltage V_{REF1} is obtained by dividing the power supply voltage V_{DD}, and is expressed by Equation (5) below.

$${V}_{REF 1} = {V}_{D D} \times {R}_{4} / ( {R}_{4} + {R}_{5} ) \qquad ( 5 )$$

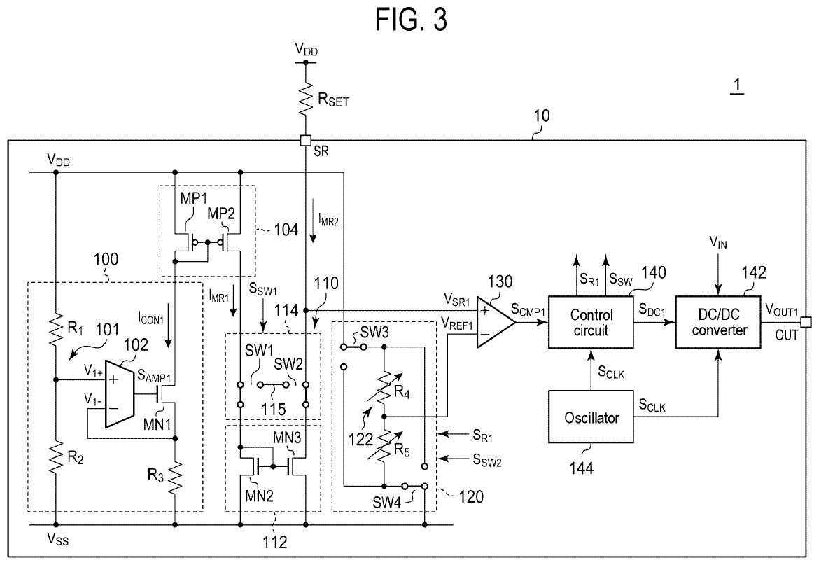

FIG. 3 is a diagram for explaining an example of an operation of the semiconductor device 10 when the fixed voltage at one end of the set resistor R_{SET} is the power supply voltage V_{DD}. As shown in FIG. 3, the application terminal of the power supply voltage V_{DD} is connected to one end of the set resistor R_{SET}. Therefore, the set resistor R_{SET} is a pull-up resistor.

When the set resistor R_{SET} is the pull-up resistor, the switching circuit 114 may be set to a pull-up type. Specifically, the first switch SW1 connects the drain of the transistor MP2 to the drain of the transistor MN2, and the second switch SW2 connects the setting terminal SR to the drain of the transistor MN3.

The current I_{MR1} generated by the first current mirror circuit 104 by copying the constant current I_{CON1} is copied by the second current mirror circuit 112. A current I_{MR2} generated by the second current mirror circuit 112 by copying the current I_{MR1} flows through the set resistor R_{SET}. At this time, the voltage V_{SR1} is generated at the setting terminal SR according to the current I_{MR2}, and is expressed by Equation (6) below.

$${V}_{SR 1} = {V}_{D D} - {R}_{S E T} \times {I}_{MR 2} \qquad ( 6 )$$

When the set resistor R_{SET} is the pull-up resistor, the reference voltage circuit 120 may be set to a pull-up type. Specifically, the third switch SW3 connects the application terminal of the power supply voltage V_{DD} to one end of the resistor R₄ opposite the resistor R₅, and the fourth switch SW4 connects one end of the resistor R₅ opposite the resistor R₄ to the ground. The reference voltage V_{REF1} is obtained by dividing the power supply voltage V_{DD}, and is expressed by Equation (7) below.

$${V}_{REF 1} = {V}_{D D} \times {R}_{5} / ( {R}_{4} + {R}_{5} ) \qquad ( 7 )$$

In the semiconductor device 10 according to this embodiment, the power supply voltage of the constant current circuit 100, the power supply voltage of the first current mirror circuit 104, the power supply voltage of one end of the set resistor R_{SET}, and the power supply voltage divided by the reference voltage circuit 120 are all common to V_{DD}. Therefore, when a fluctuation occurs in the power supply voltage V_{DD}, the constant current I_{CON1} and the reference voltage V_{REF1} also fluctuate in proportion to the fluctuation, so that the semiconductor device 10 is a circuit that is resistant to the fluctuation in the power supply voltage V_{DD}.

Specifically, when the power supply voltage V_{DD} fluctuates by n times, a terminal voltage V_{SR1′} and a reference voltage V_{REF1′} are expressed by Equations below.

$${V}_{SR {1}^{′}} = ( {V}_{D D} \times n ) - ( {R}_{S E T} \times {I}_{MR 2} \times n ) = n \times {V}_{SR 1}$$

$${V}_{REF {1}^{′}} = {V}_{D D} \times n \times {R}_{5} / ( {R}_{4} + {R}_{5} ) = n \times {V}_{REF 1}$$

In this way, the terminal voltage V_{SR1} and the reference voltage V_{REF1} follow the fluctuation in the power supply voltage V_{DD}, so the influence of the fluctuation in the power supply voltage V_{DD} on the comparison result in the comparator 130 is suppressed.

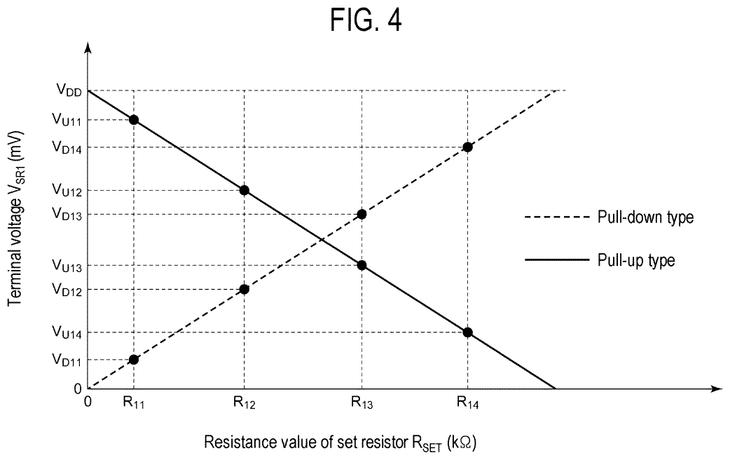

FIG. 4 is a diagram showing a relationship between the resistance value of the set resistor R_{SET} and the terminal voltage V_{SR1}. In FIG. 4, the terminal voltage V_{SR1} expressed by Equation (4) is indicated by a broken line, and the terminal voltage V_{SR1} expressed by Equation (6) is shown by a solid line. In this embodiment, the set resistor R_{SET} may take four resistance values, R₁₁ to R14. Here, R₁₁<R₁₂<R₁₃<R₁₄. The number of resistance values that the set resistor R_{SET} may take may be three or less, or may be five or more.

In the case of the pull-down type, when the set resistor R_{SET} has the resistance values R₁₁ to R₁₄, the terminal voltage V_{SR1} is V_{D11} to V_{D14}. Here, V_{D11}<V_{D12}<V_{D13}<V_{D14}. On the other hand, in the case of the pull-up type, when the set resistor R_{SET} has the resistance values R₁₁ to R₁₄, the terminal voltage V_{SR1} is V_{U11} to V_{U14}. Here, V_{U11}>V_{U12}>V_{U13}>V_{U14}.

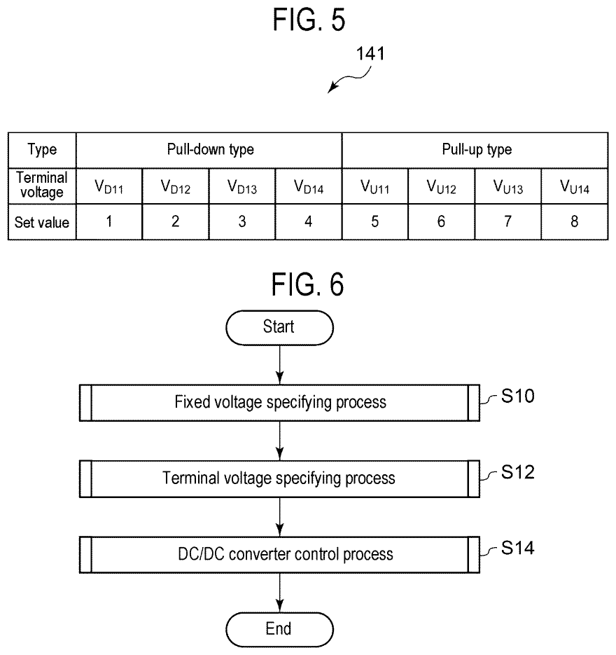

FIG. 5 is a diagram showing a table 141 in which set values are associated with the types of the set resistor R_{SET} and the voltages V_{D11} to V_{D14} and V_{U11} to V_{U14} of the setting terminal SR. The components of the semiconductor device 10 will be described in more detail below with reference to FIG. 5.

As shown in FIG. 5, different fixed voltages at one end of a set resistor R_{SET1} are associated with voltages (terminal voltages V_{SR1}) at the other ends of a plurality of set resistors R_{SET1}, each having a different magnitude. More specifically, the pull-down type is associated with the voltages V_{D11} to V_{D14}, and the pull-up type is associated with the voltages V_{U11} to V_{U14}.

Different operations are associated with the plurality of terminal voltages V_{SR1} associated with the fixed voltages at one end of the set resistor R_{SET}, respectively. In this embodiment, different set values are associated with the voltages V_{D11} to V_{D14} and V_{U11} to V_{U14}, and different operations are assigned to each set value. As a result, the different operations are associated with the voltages V_{D11} to V_{D14} and V_{U11} to V_{U14}.

Specifically, set values 1 to 4 are associated with the voltages V_{D11} to V_{D14} associated with the pull-down type. Further, set values 5 to 8 are associated with the voltages V_{U11} to V_{U14} associated with the pull-up type. Different operations of the DC/DC converter 142 are assigned to these set values 1 to 8. Thus, the DC/DC converter 142 may perform eight different operations.

For example, operations that differ in the voltage value of the output voltage V_{OUT1} of the DC/DC converter 142 and in the control method of the DC/DC converter 142 may be assigned to the set values. The control method of the DC/DC converter 142 may be, for example, PFM (Pulse Frequency Modulation) control, FPWM (Forced Pulse Width Modulation) control, or the like.

The reference voltage circuit 120 according to this embodiment may generate a voltage for specifying the terminal voltage V_{SR1}.

For example, in the case of the pull-down type, the reference voltage circuit 120 may generate a first reference voltage V_{DREF1}, a second reference voltage V_{DREF2}, a third reference voltage V_{DREF3}, and a fourth reference voltage V_{DREF4}. The first reference voltage V_{DREF1} satisfies the relationship of V_{D11}<V_{DREF1}<V_{D12}, the second reference voltage V_{DREF2} satisfies the relationship of V_{D12}<V_{DREF2}<V_{D13}, the third reference voltage V_{DREF3} satisfies the relationship of V_{D13}<V_{DREF3}<V_{D14}, and the fourth reference voltage V_{DREF4} satisfies the relationship of V_{D14}<V_{DREF4}<V_{DD}.

In the case of the pull-up type, the reference voltage circuit 120 may generate a first reference voltage V_{UREF1}, a second reference voltage V_{UREF2}, a third reference voltage V_{UREF3}, and a fourth reference voltage V_{UREF4}. The first reference voltage V_{UREF1} satisfies the relationship of V_{U14}<V_{UREF1}<V_{U13}, the second reference voltage V_{UREF2} satisfies the relationship of V_{U13}<V_{UREF2}<V_{U12}, the third reference voltage V_{UREF3} satisfies the relationship of V_{U12}<V_{UREF3}<V_{U11}, and the fourth reference voltage V_{UREF4} satisfies the relationship of V_{U11}<V_{UREF4}<V_{DD}.

The reference voltage circuit 120 according to this embodiment may sequentially switch the magnitude of the reference voltage V_{REF1} based on the comparison result obtained by the comparator 130. For example, the reference voltage circuit 120 may sequentially increase the magnitude of the reference voltage V_{REF1} from V_{DREF1} and V_{UREF1} based on the comparison result obtained by the comparator 130. Alternatively, the reference voltage circuit 120 may sequentially decrease the magnitude of the reference voltage V_{REF1} from V_{DREF4} and V_{UREF4} based on the comparison result obtained by the comparator 130.

The control circuit 140 according to this embodiment refers to the table 141 to determine the operation to be performed by the DC/DC converter 142, and may cause the DC/DC converter 142 to perform the determined operation. Specifically, the control circuit 140 specifies the fixed voltage at one end of the set resistor R_{SET}, and specifies the terminal voltage V_{SR1} when the currents I_{MR1} and I_{MR2} corresponding to the constant current I_{CON1} flow through the set resistor R_{SET}. The control circuit 140 determines the operation to be performed by the DC/DC converter 142 as an operation assigned to the set value associated with the specified fixed voltage at one end of the set resistor R_{SET} and the specified terminal voltage V_{SR1}.

The control circuit 140 according to this embodiment specifies the fixed voltage at one end of the set resistor R_{SET} based on the comparison result obtained by the comparator 130 when no current flows through the set resistor R_{SET}. Further, the control circuit 140 specifies the voltage (terminal voltage V_{SR1}) at the other end of the set resistor R_{SET} based on the comparison result obtained by the comparator 130 when the currents I_{MR1} and I_{MR2} corresponding to the constant current I_{CON1} flow through the set resistor R_{SET}. Furthermore, the control circuit 140 causes the DC/DC converter 142 to perform an operation associated with the specified fixed voltage at one end of the set resistor R_{SET} and the specified voltage at the other end of the set resistor R_{SET}.

The control circuit 140 according to this embodiment specifies the terminal voltage V_{SR1} based on the comparison result obtained by the comparator 130 corresponding to the sequential switching of the magnitude of the reference voltage V_{REF1}, and causes the DC/DC converter 142 to perform an operation associated with the specified terminal voltage V_{SR1}. For example, in the case of the pull-down type, if the comparison result obtained by the comparator 130 indicates that the terminal voltage V_{SR1} is larger than the second reference voltage V_{DREF2} and smaller than the third reference voltage V_{DREF3}, the control circuit 140 may specify that the terminal voltage V_{SR1} is the voltage V_{D13}. In this case, the control circuit 140 causes the DC/DC converter 142 to perform an operation associated with the voltage V_{D13}, that is, an operation assigned to the set value 3.

FIG. 6 is a flowchart showing an example of the operation of the semiconductor device 10 according to this embodiment. Hereinafter, an example of the operation of the semiconductor device 10 will be described with reference to the flowchart shown in FIG. 6.

First, the semiconductor device 10 executes a fixed voltage specifying process (S10). The fixed voltage specifying process is a fixed voltage specifying process at one end of the set resistor R_{SET}. Next, the semiconductor device 10 executes a terminal voltage specifying process (S12). The terminal voltage specifying process is a process of specifying the terminal voltage V_{SR1} when a current corresponding to the constant current I_{CON1} flows through the set resistor R_{SET}.

Next, the semiconductor device 10 executes a DC/DC converter control process (S14). The DC/DC converter control process is a process of causing the DC/DC converter 142 to perform an operation associated with the fixed voltage specified in S10 and the terminal voltage V_{SR1} specified in S12. After the DC/DC converter control process is executed, the process shown in FIG. 6 ends.

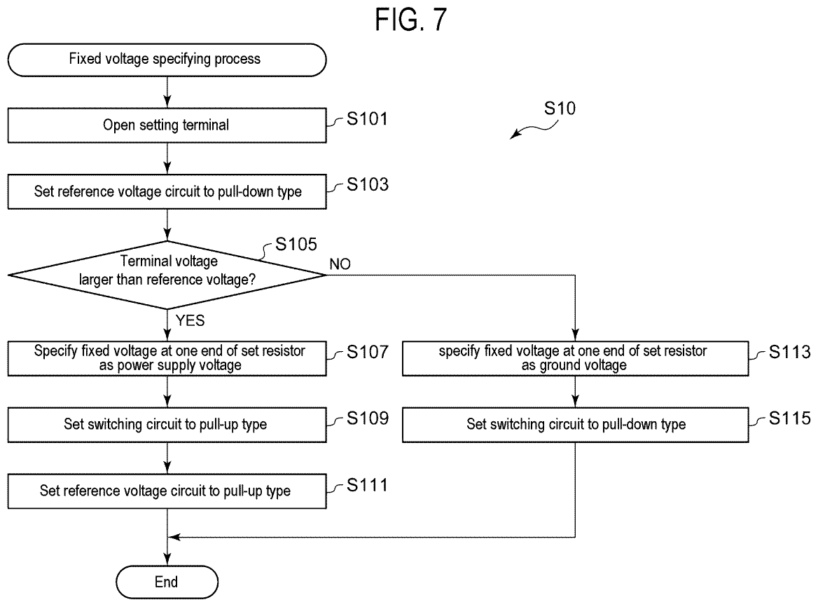

FIG. 7 is a flowchart showing an example of the fixed voltage specifying process (S10) according to this embodiment. A flow of the fixed voltage specifying process will be described below with reference to the flowchart shown in FIG. 7.

First, the control circuit 140 opens the setting terminal SR (S101). Specifically, the control circuit 140 switches the second switch SW2 so that the setting terminal SR is not connected to either the common line 115 or the drain of the transistor MN3. As a result, no current flows through the set resistor R_{SET}, and the terminal voltage V_{SR1} becomes a fixed voltage at one end of the set resistor R_{SET}.

Next, the control circuit 140 sets the reference voltage circuit 120 to a pull-down type (S103). As a result, the reference voltage V_{REF1}, which is obtained by dividing the power supply voltage V_{DD}, is generated.

Next, the comparator 130 determines whether or not the terminal voltage V_{SR1} is larger than the reference voltage V_{REF1} (S105). When it is determined that the terminal voltage V_{SR1} is larger than the reference voltage V_{REF1} (S105: YES), the process proceeds to step S107. On the other hand, when it is determined that the terminal voltage V_{SR1} is smaller than the reference voltage V_{REF1} (S105: NO), the process proceeds to S113.

When it is determined in S105 that the terminal voltage V_{SR1} is larger than the reference voltage V_{REF1}, the control circuit 140 specifies the fixed voltage at one end of the set resistor R_{SET} as the power supply voltage V_{DD} (S107). Next, the control circuit 140 sets the switching circuit 114 to a pull-up type (S109). Next, the control circuit 140 sets the reference voltage circuit 120 to a pull-up type (S111). When the reference voltage circuit 120 is set to the pull-up type, the fixed voltage specifying process ends.

When it is determined in S105 that the terminal voltage V_{SR1} is smaller than the reference voltage V_{REF1}, the control circuit 140 specifies the fixed voltage at one end of the set resistor R_{SET} as the ground voltage (S113). Next, the control circuit 140 sets the switching circuit 114 to a pull-down type (S115). When the switching circuit 114 is set to the pull-down type, the fixed voltage specifying process ends.

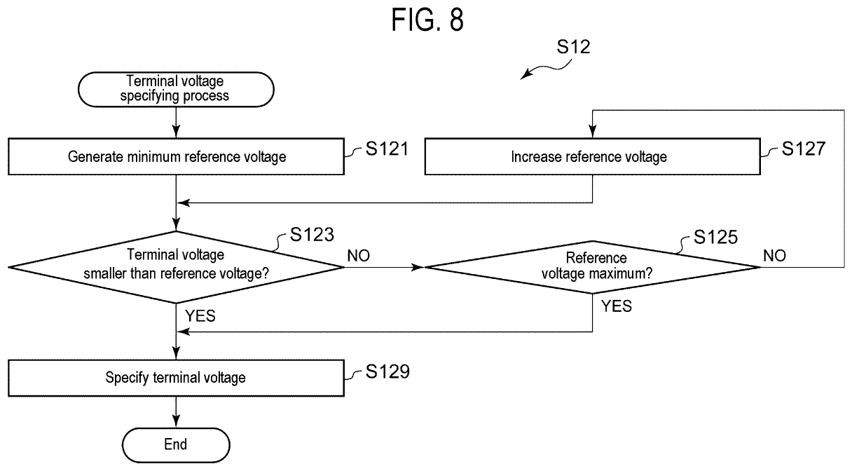

FIG. 8 is a flowchart showing an example of the terminal voltage specifying process (S12) according to this embodiment. A flow of the terminal voltage specifying process will be described below with reference to the flowchart shown in FIG. 8.

First, the reference voltage circuit 120 generates a minimum reference voltage V_{REF1} (S121). In the case of the pull-down type, the minimum reference voltage V_{REF1} is the first reference voltage V_{DREF1}, and in the case of the pull-up type, it is the first reference voltage V_{UREF1}.

Next, the comparator 130 determines whether or not the terminal voltage V_{SR1} is smaller than the reference voltage V_{REF1} (S123). When it is determined that the terminal voltage V_{SR1} is smaller than the reference voltage V_{REF1} (S123: YES), the process proceeds to S129. On the other hand, when it is determined that the terminal voltage V_{SR1} is larger than the reference voltage V_{REF1} (S123: NO), the process proceeds to S125.

When it is determined in S123 that the terminal voltage V_{SR1} is larger than the reference voltage V_{REF1}, the control circuit 140 determines whether or not the reference voltage V_{REF1} is maximum (S125). The control circuit 140 may determine that the reference voltage V_{REF1} is maximum when the reference voltage V_{REF1} is the third reference voltage V_{DREF3} and V_{UREF3}, and may determine that the reference voltage V_{REF1} is not maximum when the reference voltage V_{REF1} is smaller than the third reference voltage V_{DREF3} and V_{UREF3}. When it is determined that the reference voltage V_{REF1} is maximum (S125: YES), the process proceeds to S129. On the other hand, when it is determined that the reference voltage V_{REF1} is not maximum (S125: NO), the process proceeds to S127.

When it is determined in S125 that the reference voltage V_{REF1} is not maximum, the control circuit 140 increases the reference voltage V_{REF1} (S127). When the reference voltage V_{REF1} is the first reference voltage V_{DREF1} and V_{UREF1}, the control circuit 140 may increase the reference voltage V_{REF1} to the second reference voltage V_{DREF2} and V_{UREF2}, and when the reference voltage V_{REF1} is the second reference voltage V_{DREF2} and V_{UREF2}, the control circuit 140 may increase the reference voltage V_{REF1} to the third reference voltage V_{DREF3} and V_{UREF3}. When the reference voltage V_{REF1} increases, the process returns to S123.

When it is determined in S123 that the terminal voltage V_{SR1} is smaller than the reference voltage V_{REF1}, or when it is determined in S125 that the reference voltage V_{REF1} is maximum, the control circuit 140 specifies the terminal voltage V_{SR1} (S129).

When it is determined in S123 that the terminal voltage V_{SR1} is lower than the reference voltage V_{REF1}, in the case of the pull-down type, the control circuit 140 may specify a voltage among the voltages V_{D11} to V_{D14}, which is lower than the reference voltage V_{REF1} in S123 and closest to the reference voltage V_{REF1}, as the terminal voltage V_{SR1}. For example, when the reference voltage V_{REF1} in S123 is the third reference voltage V_{DREF3}, the control circuit 140 may specify the terminal voltage V_{SR1} as the voltage V_{D13}. Further, in the case of the pull-up type, the control circuit 140 may specify a voltage among the voltages V_{U11} to V_{U14}, which is lower than the reference voltage V_{REF1} in S123 and closest to the reference voltage V_{REF1}, as the terminal voltage V_{SR1}.

When it is determined in S125 that the reference voltage V_{REF1} is maximum, in the case of the pull-down type, the control circuit 140 may specify the terminal voltage V_{SR1} as the voltage V_{D14}. In the case of the pull-up type, the control circuit 140 may specify the terminal voltage V_{SR1} as the voltage V_{U14}.

When the terminal voltage V_{SR1} is specified in S129, the terminal voltage specifying process ends.

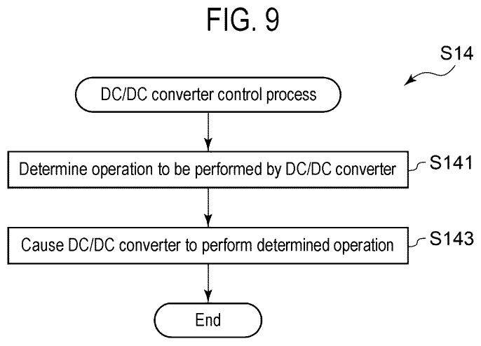

FIG. 9 is a flowchart showing an example of the DC/DC converter control process (S14) according to this embodiment. A flow of the DC/DC converter control process will be described below with reference to the flowchart shown in FIG. 9.

First, the control circuit 140 determines an operation to be performed by the DC/DC converter 142 (S141). The control circuit 140 determines the operation to be performed by the DC/DC converter 142 to be the operation associated with the fixed voltage specified in S10 at one end of the set resistor R_{SET} and the terminal voltage V_{SR1} specified in S12. For example, if the fixed voltage at one end of the set resistor R_{SET} is specified as the power supply voltage V_{DD} and the terminal voltage V_{SR1} is specified as the voltage V_{U13}, the control circuit 140 may determine the operation to be performed by the DC/DC converter 142 to be an operation assigned to the set value 7.

Next, the control circuit 140 causes the DC/DC converter 142 to perform the operation determined in S141 (S143). When the DC/DC converter 142 performs the determined operation, the DC/DC converter control process ends.

The configurations and operations of the system 1 and the semiconductor device 10 thereof according to this embodiment have been described above. The semiconductor device 10 according to this embodiment includes the constant current circuit 100 that generates the constant current I_{CON1}, and the operating circuit (the DC/DC converter 142) that performs the operation associated with the fixed voltage at one end of the set resistor R_{SET} and the voltage (the terminal voltage V_{SR1}) at the other end of the set resistor R_{SET} through which the current corresponding to the constant current I_{CON1} flows. The terminal voltage V_{SR1} is a voltage corresponding to the current flowing through the set resistor R_{SET}. Different fixed voltages at one end of the set resistor R_{SET} are associated with different operations of the DC/DC converter 142.

With this configuration, it is possible to switch the operation to be performed by the DC/DC converter 142 by switching the fixed voltage at one end of the set resistor R_{SET}. Thus, the semiconductor device 10 may perform a variety of operations by the DC/DC converter 142 as compared to a case where one fixed voltage is used.

Since variations occur in the terminal voltage V_{SR1}, the reference voltage V_{REF1}, the offset of the comparator 130, or the like, a certain distance is required between two adjacent reference voltages V_{REF1}. Therefore, when using either the pull-down resistor or the pull-up resistor, restrictions are imposed on the number of set values, and therefore on the number of operations that the DC/DC converter 142 may perform. In contrast, with the semiconductor device 10 according to this embodiment, different set values are assigned to the pull-down resistor and the pull-up resistor, thereby making it possible for the DC/DC converter 142 to perform a variety of operations.

### Second Embodiment

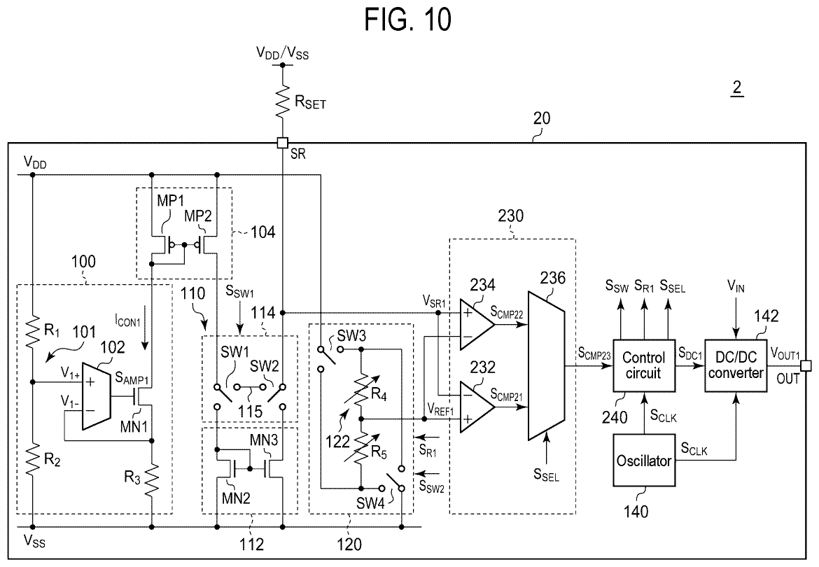

FIG. 10 is a block diagram of a system 2 according to a second embodiment. A semiconductor device 20 included in the system 2 according to the second embodiment is different from the semiconductor device 10 according to the first embodiment mainly in the configuration of the comparison circuit.

The semiconductor device 20 according to the second embodiment includes a constant current circuit 100, a first current mirror circuit 104, a direction control circuit 110, a reference voltage circuit 120, a comparison circuit 230, a control circuit 240, a DC/DC converter 142, an oscillator 144, a setting terminal SR, and an output terminal OUT.

The comparison circuit 230 according to the second embodiment includes a first comparator 232, a second comparator 234, and a multiplexer 236. The first comparator 232 and the second comparator 234 according to this embodiment are not rail-to-rail comparators, but comparators that may operate normally in a predetermined input voltage range that is narrower than the range from the ground voltage to the power supply voltage V_{DD}.

The first comparator 232 and the second comparator 234 operate normally in different input voltage ranges. In this embodiment, the first comparator 232 is configured to operate normally when an input voltage falls within a first voltage range V_{RNG1}, and the second comparator 234 is configured to operate normally when an input voltage falls within a second voltage range V_{RNG2}.

A lower limit voltage V_{MIN1} of the first voltage range V_{RNG1} is equal to or smaller than a first fixed voltage, and an upper limit voltage V_{MAX1} of the first voltage range V_{RNG1} is smaller than a second fixed voltage. In this embodiment, the lower limit voltage V_{MIN1} of the first voltage range V_{RNG1} is a ground voltage, and the upper limit voltage V_{MAX1} of the first voltage range V_{RNG1} is smaller than the power supply voltage V_{DD}. A lower limit voltage V_{MIN2} of the second voltage range V_{RNG2} is larger than the first fixed voltage, and an upper limit voltage V_{MAX2} of the second voltage range V_{RNG2} is equal to or larger than the second fixed voltage. In this embodiment, the lower limit voltage V_{MIN2} of the second voltage range V_{RNG2} is larger than the ground voltage, and the upper limit voltage V_{MAX2} of the second voltage range V_{RNG2} is the power supply voltage V_{DD}.

The first comparator 232 compares the reference voltage V_{REF1} with the terminal voltage V_{SR1} to generate a comparison signal S_{CMP21}. The comparison signal S_{CMP21} is a high-level signal when the reference voltage V_{REF1} is larger than the terminal voltage V_{SR1}, and is a low-level signal when the reference voltage V_{REF1} is smaller than the terminal voltage V_{SR1}. The second comparator 234 compares the reference voltage V_{REF1} with the terminal voltage V_{SR1} to generate a comparison signal S_{CMP22}. The comparison signal S_{CMP22} is a high-level signal when the terminal voltage V_{SR1} is larger than the reference voltage V_{REF1}, and is a low-level signal when the terminal voltage V_{SR1} is smaller than the reference voltage V_{REF1}.

The multiplexer 236 selects one of the comparison signal S_{CMP21} generated by the first comparator 232 and the comparison signal S_{CMP2} generated by the second comparator 234, and outputs a selected comparison signal S_{CMP23}. The multiplexer 236 may determine a comparison signal to be selected according to a signal S_{SEL} generated by the control circuit 240.

The control circuit 240 controls the operation of the DC/DC converter 142. The control circuit 240 according to this embodiment determines an operation to be performed by the DC/DC converter 142 based on the comparison signal S_{CMP23} output by the multiplexer 236, and generates a signal S_{DC1} for causing the DC/DC converter 142 to perform that operation.

The control circuit 240 according to this embodiment specifies the terminal voltage V_{SR1} based on the comparison result obtained by the first comparator 232 when the fixed voltage at one end of the set resistor R_{SET} is the ground voltage. Further, the control circuit 240 specifies the terminal voltage V_{SR1} based on the comparison result obtained by the second comparator 234 when the fixed voltage at one end of the set resistor R_{SET} is the power supply voltage V_{DD}. The control circuit 240 causes the DC/DC converter 142 to perform an operation associated with the specified terminal voltage V_{SR1}.

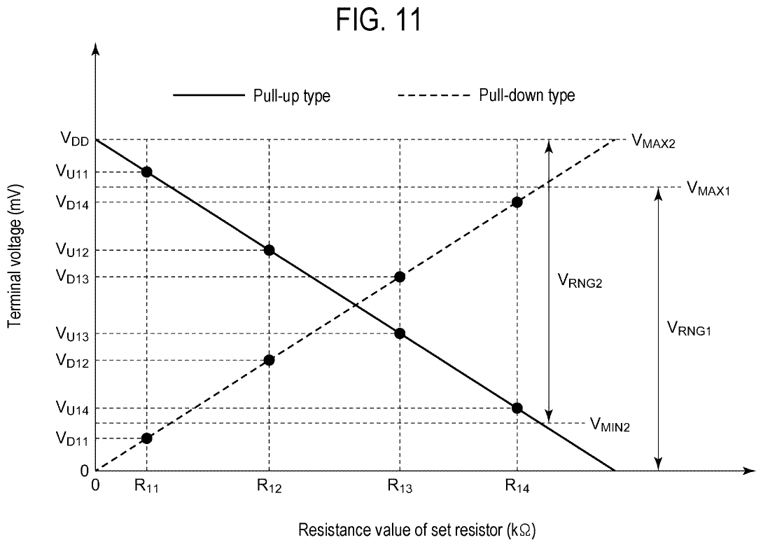

FIG. 11 is a diagram for explaining operating ranges of the first comparator 232 and the second comparator 234. The first voltage range V_{RNG1}, which is the operating range of the first comparator 232, includes values V_{D11} to V_{D14} that the terminal voltage V_{SR1} may take in the pull-down type, and the ground voltage (0 V). The lower limit voltage V_{MIN1} of the first voltage range V_{RNG1} is 0 V and the upper limit voltage V_{MAX1} of the first voltage range V_{RNG1} satisfies a relationship of V_{D14}<V_{MAX1}<V_{DD}. The second voltage range V_{RNG2}, which is the operating range of the second comparator 234, includes values V_{U11} to V_{U14} that the terminal voltage V_{SR1} may take in the pull-up type and the power supply voltage V_{DD}. The lower limit voltage V_{MIN2} of the second voltage range V_{RNG2} satisfies a relationship of 0<V_{MIN1}<V_{U11}, and the upper limit voltage V_{MAX2} of the second voltage range V_{RNG2} is V_{DD}.

The first voltage range V_{RNG1} does not include the pull-up voltage V_{U11} and the power supply voltage V_{DD}, and the second voltage range V_{RNG2} does not include the pull-down V_{D11} and the ground voltage. In this way, even if one comparator cannot cover all voltages from the ground voltage to the power supply voltage V_{DD}, it is possible to cover all voltages from the ground voltage to the power supply voltage V_{DD} by using two comparators such as the first comparator 232 and the second comparator 234.

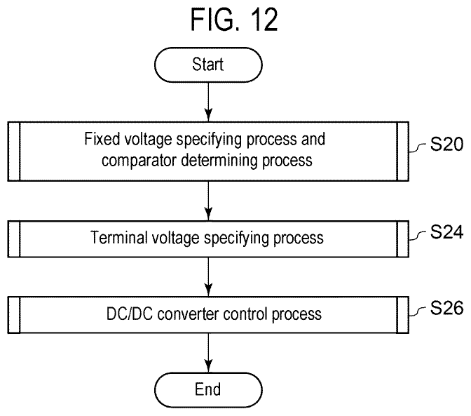

FIG. 12 is a flowchart showing an example of an operation of the semiconductor device 20 according to the second embodiment. The example of the operation of the semiconductor device 20 will be described below with reference to the flowchart shown in FIG. 12.

First, the semiconductor device 20 performs a fixed voltage specifying process and a comparator determining process (S20). These processes are respectively a fixed voltage specifying process at one end of the set resistor R_{SET} and a process of determining a comparator to be used to specify the terminal voltage V_{SR1}.

Next, the semiconductor device 20 performs a terminal voltage specifying process (S24) and a DC/DC converter control process (S26). These processes are substantially the same as the terminal voltage specifying process (S12) and the DC/DC converter control process (S14) according to the first embodiment, and therefore descriptions thereof will be omitted here. When the DC/DC converter control process is performed, the process shown in FIG. 12 ends.

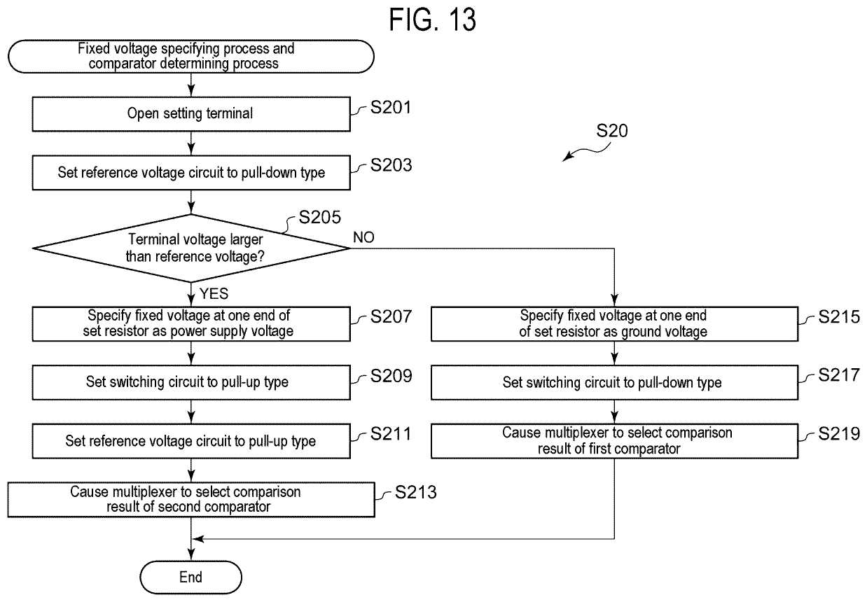

FIG. 13 is a flowchart showing an example of the fixed voltage specifying process and the comparator determining process (S20) according to this embodiment. Flows of the fixed voltage specifying process and the comparator determining process will be described below with reference to the flowchart shown in FIG. 13.

First, the control circuit 240 opens the setting terminal SR (S201). Specifically, the control circuit 240 switches the second switch SW2 so that the setting terminal SR is not connected to either the common line 115 or the drain of the transistor MN3. As a result, the terminal voltage V_{SR1} becomes the fixed voltage at one end of the set resistor R_{SET}. Next, the control circuit 240 sets the reference voltage circuit 120 to a pull-down type (S203). As a result, the reference voltage V_{REF1} is generated by dividing the power supply voltage V_{DD}.

Next, the control circuit 240 determines whether or not the terminal voltage V_{SR1} is larger than the reference voltage V_{REF1} (S205). For example, when the fixed voltage at one end of the set resistor R_{SET} is the ground voltage, the first comparator 232 operates normally and generates a high-level comparison signal S_{CMP1}. When the fixed voltage at one end of the set resistor R_{SET} is the power supply voltage V_{DD}, the second comparator 234 operates normally and generates a high-level comparison signal S_{CMP2}.

When the comparison signal S_{CMP2} generated by the second comparator 234 is a high-level signal, the control circuit 240 may determine that the terminal voltage V_{SR1} is larger than the reference voltage V_{REF1}. In addition, when the comparison signal S_{CMP1} generated by the first comparator 232 is a high-level signal, the control circuit 240 may determine that the terminal voltage V_{SR1} is smaller than the reference voltage V_{REF1}. When it is determined that the terminal voltage V_{SR1} is larger than the reference voltage V_{REF1} (S205: YES), the process proceeds to S207. On the other hand, when it is determined that the terminal voltage V_{SR1} is smaller than the reference voltage V_{REF1} (S205: NO), the process proceeds to S215.

When the control circuit 240 determines in S205 that the terminal voltage V_{SR1} is larger than the reference voltage V_{REF1}, it specifies the fixed voltage at one end of the set resistor R_{SET} as the power supply voltage V_{DD} (S207). Next, the control circuit 240 sets the switching circuit 114 to a pull-up type (S209). Next, the control circuit 240 sets the reference voltage circuit 120 to a pull-up type (S211). Next, the control circuit 240 causes the multiplexer 236 to select the comparison result (the comparison signal S_{CMP2}) of the second comparator 234 (S213). When the multiplexer 236 selects the comparison result obtained by the second comparator 234, the fixed voltage specifying process and the comparator determining process are completed.

When the control circuit 240 determines in S205 that the terminal voltage V_{SR1} is smaller than the reference voltage V_{REF1}, it specifies the fixed voltage at one end of the set resistor R_{SET} as the ground voltage (S215). Next, the control circuit 240 sets the switching circuit 114 to a pull-down type (S217). Next, the control circuit 240 causes the multiplexer 236 to select the comparison result (the comparison signal S_{CMP1}) of the first comparator 232 (S219). When the multiplexer 236 selects the comparison result obtained by the first comparator 232, the fixed voltage specifying process and the comparator determining process are completed.

### Third Embodiment

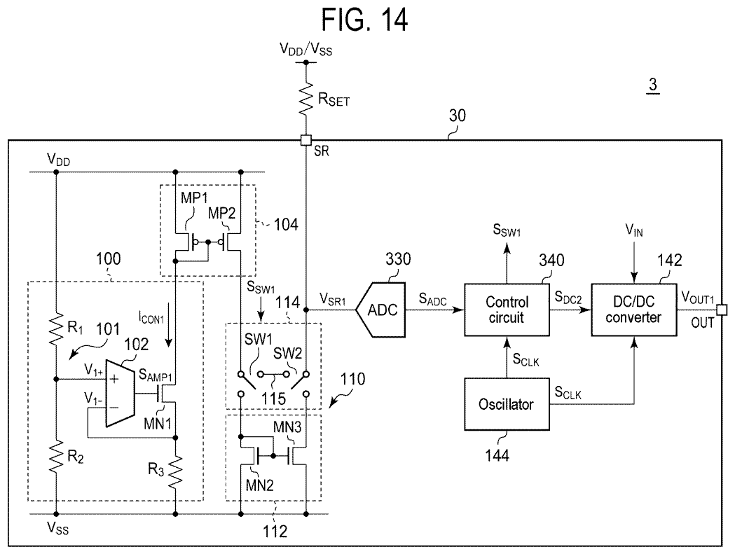

FIG. 14 is a block diagram of a system 3 according to a third embodiment. A semiconductor device 30 included in the system 3 according to the third embodiment is different from the semiconductor devices 10 and 20 according to the above-described embodiments mainly in that the former uses an A/D converter, instead of a comparator, to determine the fixed voltage at one end of the set resistor R_{SET} and the terminal voltage V_{SR1}.

The semiconductor device 30 according to the third embodiment includes a constant current circuit 100, a first current mirror circuit 104, a direction control circuit 110, an A/D converter 330, a control circuit 340, a DC/DC converter 142, an oscillator 144, a setting terminal SR, and an output terminal OUT.

The A/D converter 330 converts the voltage (the terminal voltage V_{SR1}) at the other end of the set resistor R_{SET} into a digital signal S_{ADC}.

The control circuit 340 determines an operation to be performed by the DC/DC converter 142 based on the digital signal S_{ADC}. Specifically, the control circuit 340 determines a fixed voltage at one end of the set resistor R_{SET} based on the digital signal S_{ADC} when no current flows through the set resistor R_{SET}. The control circuit 340 also determines a terminal voltage V_{SR1} based on the digital signal S_{ADC} when a current corresponding to the constant current I_{CON1} flows through the set resistor R_{SET}. Further, the control circuit 340 causes the DC/DC converter 142 to perform an operation associated with the determined terminal voltage V_{SR1}. The control circuit 340 may refer to the table 141 as necessary.

### Fourth Embodiment

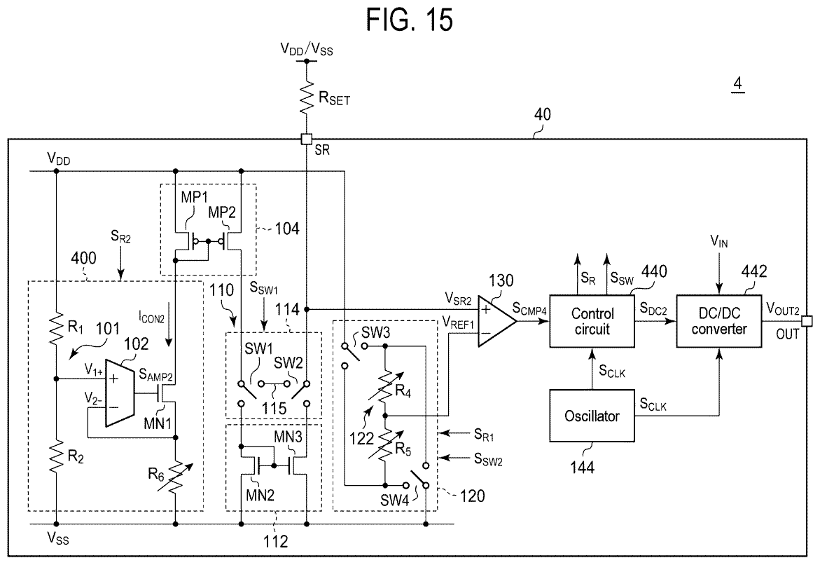

FIG. 15 is a block diagram of a system 4 according to a fourth embodiment. A semiconductor device 40 included in the system 4 according to the fourth embodiment is different from the semiconductor devices 10, 20, and 30 according to the above-described embodiments mainly in that the magnitude of a constant current I_{CON2} is switchable, and in addition to the fixed voltage at one end of the set resistor R_{SET} and a terminal voltage V_{SR2} when a current according to the constant current I_{CON2} flows through the set resistor R_{SET}, the semiconductor device 40 performs an operation associated with the constant current I_{CON2}.

The semiconductor device 40 according to the fourth embodiment includes a constant current circuit 400, a first current mirror circuit 104, a direction control circuit 110, a reference voltage circuit 120, a comparator 130, a control circuit 440, a DC/DC converter 442, an oscillator 144, a setting terminal SR, and an output terminal OUT. The semiconductor device 40 performs an operation according to a set value corresponding to the resistance value of the set resistor R_{SET}, and outputs an output voltage V_{OUT2} from the output terminal OUT.

The constant current circuit 400 according to this embodiment generates a constant current I_{CON2} and is configured to be capable of switching the magnitude of the constant current I_{CON2}. In the constant current circuit 400, a variable resistor R₆ is provided instead of the resistor R₃ according to the above-described embodiments. When the constant current I_{CON2} flows through the resistor R₆, a voltage V2− is generated at one end of the resistor R₆ on a side of the transistor MN1. The voltage V₂₋ is input to the inverting input terminal of the operational amplifier 102.

The operational amplifier 102 generates an output voltage S_{AMP2} so that the voltage V₁₊ input to the non-inverting input terminal and the voltage V₂₋ input to the inverting input terminal are the same (that is, V₁₊=V₂₋). Therefore, the constant current I_{CON2} is expressed by Equation (8) below.

$${I}_{CON 2} = {V}_{D D} \times {R}_{2} / \{ {R}_{6} \times ( {R}_{1} + {R}_{2} ) \} \qquad ( 8 )$$

By switching the resistance value of the resistor R₆, the magnitude of the constant current I_{CON2} may be switched according to Equation (8). Further, the resistors R₁ and R₂ may be variable resistors, and the magnitude of the constant current I_{CON2} may be switched by switching the voltage division ratio in the voltage divider circuit 101.

The comparator 130 according to this embodiment compares the reference voltage V_{REF1} with the voltage (the terminal voltage V_{SR2}) of the setting terminal SR to generate a comparison signal S_{CMP4} indicating the comparison result. The comparison signal S_{CMP4} is input to the control circuit 440.

The control circuit 440 according to this embodiment causes the DC/DC converter 442 to perform an operation associated with the constant current I_{CON2} generated by the constant current circuit 400, in addition to the fixed voltage at one end of the set resistor R_{SET} and the terminal voltage V_{SR2}. Different operations of the DC/DC converter 442 are associated with the constant currents I_{CON2} of different magnitudes generated by the constant current circuit 400.

The control circuit 440 according to this embodiment determines an operation associated with the fixed voltage at one end of the set resistor R_{SET}, the terminal voltage V_{SR2}, and the constant current I_{CON2} based on the comparison signal S_{CMP4}, and generates a control signal S_{DC2} for causing the DC/DC converter 442 to perform the determined operation.

The control circuit 440 may generate a signal SSW for switching a switch and a signal S_{R} for switching a resistance value. The signal S_{R} includes a signal S_{R1} for switching the resistance values of the resistors R₄ and R₅ of the reference voltage circuit 120 and a signal S_{R2} for switching the resistance value of the resistor R₆ of the constant current circuit 400.

The DC/DC converter 442 generates the output voltage V_{OUT2} according to the input voltage V_{IN}. The DC/DC converter 442 performs an operation associated with the constant current I_{CON2} generated by the constant current circuit 400, in addition to the fixed voltage at one end of the set resistor R_{SET} and the voltage (the terminal voltage V_{SR2}) at the other end of the set resistor R_{SET} through which a current corresponding to the constant current I_{CON2} flows. In this embodiment, the DC/DC converter 442 performs an operation determined by the control circuit 440.

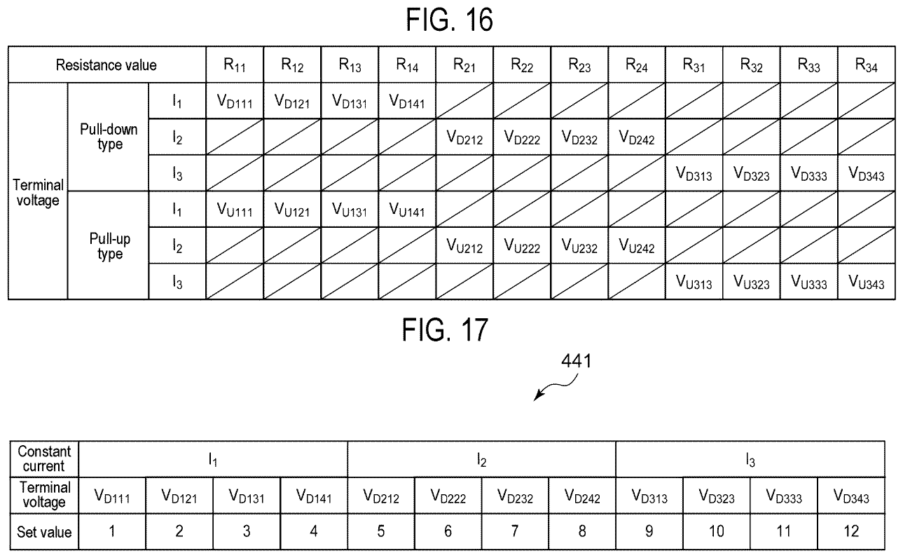

FIG. 16 is a diagram showing a relationship between the resistance value of the set resistor R_{SET}, the type of the set resistor R_{SET}, the constant current I_{CON2}, and the terminal voltage V_{SR2} according to this embodiment.

The resistance values R₁₁ to R₁₄, R₂₁ to R₂₄, and R₃₁ to R₃₄ shown in the top row of FIG. 16 are resistance values that the set resistor R_{SET} according to this embodiment may take. The larger the subscript, the larger the resistance values R₁₁ to R₁₄, R₂₁ to R₂₄, and R₃₁ to R₃₄. While FIG. 16 shows twelve resistance values that the set resistor R_{SET} may take, but the number of resistance values for the set resistor R_{SET} may be eleven or less, or thirteen or more.

In this embodiment, the resistance values R₂₁ to R₂₄ (second resistance values) are N times (N is a number larger than 1) the resistance values R₁₁ to R₁₄ (first resistance values), and the resistance values R₃₁ to R₃₄ (third resistance values) are N times the resistance values R₂₁ to R₂₄. Specifically, N²×R₁₁=N×R₂₁=R₃₁, N²×R₁₂=N×R₂₂=R₃₂, N²×R₁₃=N×R₂₃=R₃₃, and N²×R₁₄=N×R₂₄=R₃₄. N may be, for example, about 10.

Current values I₁ to I₃ shown in FIG. 16 are current values that the constant current I_{CON2} may take. Therefore, the constant current circuit 400 according to this embodiment generates a constant current I_{CON2} having one of the current values I₁ to I₃. The current values I₁ to I₃ satisfy a relationship of I₁>I₂>I₃. More specifically, I₁/N²=I₂/N=I₃. Although FIG. 16 shows three current values I₁ to I₃, the number of current values that the constant current I_{CON2} may take may be two, or may be four or more.

The constant current circuit 400 according to this embodiment generates a first constant current when the resistance value of the set resistor R_{SET} is a first resistance value, and generates a second constant current having the magnitude of 1/N times that of the first constant current when the resistance value of the set resistor R_{SET} is a second resistance value that is N times the first resistance value. Specifically, when the resistance value of the set resistor R_{SET} is R₁₁ to R₁₄, the constant current circuit 400 generates a constant current I_{CON2} (the first constant current) having the current value I₁. When the resistance value of the set resistor R_{SET} is R₂₁ to R₂₄, the constant current circuit 400 generates a constant current I_{CON2} (the second constant current) having the current value I₂. When the resistance value of the set resistor R_{SET} is R₃₁ to R₃₄, the constant current circuit 400 generates a constant current I_{CON2} (the third constant current) having the current value I₃.

Each of voltages V_{D111} to V_{D141}, V_{D212} to V_{D242}, V_{D313} to V_{D343}, V_{U111} to V_{U141}, V_{U212} to V_{U242}, and V_{U313} to V_{U343} shown in FIG. 16 indicates a terminal voltage V_{SR2} that should be generated when the resistance of the set resistor R_{SET} is the resistance value of a corresponding column and the magnitude of the constant current I_{CON2} is the current value of a corresponding row. The voltages V_{D111} to V_{D141}, V_{D212} to V_{D242}, and V_{D313} to V_{D343} are voltages when the set resistor R_{SET} is a pull-down resistor (pull-down type). The voltages V_{U111} to V_{U141}, V_{U212} to V_{U242}, and V_{U313} to V_{U343} are voltages when the set resistor R_{SET} is a pull-up resistor (pull-up type). Here, it is assumed that the magnitude of the constant current I_{CON2} is the same as the magnitude of the current flowing through the set resistor R_{SET}.

In this embodiment, there is a plurality of combinations of the resistance values of the set resistor R_{SET} and the current values of the constant current I_{CON2}, which result in the same terminal voltage V_{SR2} to be generated. For example, V_{D111} is V_{D111}=R₁₁×I₁. In addition, V_{D212} is V_{D212}=R₂×I₂=(N×R₁₁)×(I₁/N)=R₁₁×I₁=V_{D111}. Further, V_{D313} is V_{D313}=R₃×I₃=(N²×R₁₁)×(I₁N²)=R₁₁×I₁=V_{D111}. Therefore, V_{D111}=V_{D212}=V_{D313}. Similarly, V_{D121}=V_{D222}=V_{D323}, V_{D131}=V_{D232}=V_{D333}, and V_{D141}=V_{D242}=V_{D343}. Further, V_{U111}=V_{U212}=V_{U313}, V_{U121}=V_{U222}=V_{U323}, V_{U131}=V_{U232}=V_{U333}, and V_{U141}=V_{U242}=V_{U343}.

In FIG. 16, the shaded areas are areas that are not suitable for associating set values. For example, in the case of the pull-down type, when a current value is I₁ and a resistance value of the set resistor R_{SET} is R₂₁, a relationship of R₂₁×I₁>V_{DD} is established, and the terminal voltage V_{SR2} according to the resistance value of the set resistor R_{SET} cannot be generated appropriately.

FIG. 17 is a diagram showing a table 441 in which set values are associated with the current values I₁ to I₃ of the constant current I_{CON2} and the voltages V_{D111} to V_{D141}, V_{D212} to V_{D242}, and V_{D313} to V_{D343} of the setting terminal SR in the pull-down type. The components of the semiconductor device 40 will be described in more detail below with reference to FIG. 17.

As shown in FIG. 17, the constant current I_{CON2} generated by the constant current circuit 400 is associated with the voltages (the terminal voltages V_{SR2}) at the other ends of a plurality of set resistors R_{SET} having different magnitudes. Specifically, the constant current I_{CON2} having the current value I₁ is associated with the voltages V_{D111} to V_{D141}, the constant current I_{CON2} having the current value I₂ is associated with the voltages V_{D212} to V_{D242}, and the constant current I_{CON2} having the current value I₃ is associated with the voltages V_{D313} to V_{D343}.

Different operations are associated with the voltages V_{D111} to V_{D141}, the voltages V_{D212} to V_{D242}, and the voltages V_{D313} to V_{D343}. Specifically, set values 1 to 4 are associated with the voltages V_{D111} to V_{D141} associated with the constant current I_{CON2} having the current value I₁. In addition, set values 5 to 8 are associated with the voltages V_{D212} to V_{D242} associated with the constant current I_{CON2} having the current value I₂. Further, set values 9 to 12 are associated with the voltages V_{D313} to V_{D343} associated with the constant current I_{CON2} having a current value I₃. Similarly, set values 13 to 24 are associated with the voltages V_{U111} to V_{U141}, V_{U212} to V_{U242}, and V_{U313} to V_{U343} in the pull-up type. Different operations of the DC/DC converter 442 are assigned to these set values 1 to 24. Thus, the DC/DC converter 442 may perform twelve different operations.

The constant current circuit 400 according to this embodiment may generate, as the reference voltage V_{REF1}, an upper or lower limit voltage of the range V_{RNG3} of a voltage to be generated at the setting terminal SR. The voltage range V_{RNG3} mainly includes voltages associated with the set values and does not include voltages not associated with the set values. The lower limit voltage V_{MIN3} of the voltage range V_{RNG3} according to this embodiment is larger than 0 V and smaller than the smallest of voltages that the terminal voltage V_{SR2} may take. Specifically, in the case of the pull-down type, the voltage V_{MIN3} satisfies a relationship of 0<V_{MIN3}<V_{D111}. Further, in the case of the pull-up type, the voltage V_{MIN3} satisfies a relationship of 0<V_{MIN3}<V_{U141}.

The upper limit voltage V_{MAX3} of the voltage range V_{RNG3} according to this embodiment is larger than the largest of voltages that the terminal voltage V_{SR2} may take and smaller than the power supply voltage V_{DD}. Specifically, in the case of the pull-down type, the voltage V_{MAX3} satisfies a relationship of V_{D141}<V_{MAX3}<V_{DD}. Further, in the case of the pull-up type, the voltage V_{MAX3} satisfies a relationship of V_{D111}<V_{MAX3}<V_{DD}.

The constant current circuit 400 according to this embodiment switches the magnitude of the constant current I_{CON2} so that the terminal voltage V_{SR2} falls within the voltage range V_{RNG3} when the terminal voltage V_{SR2} falls outside the range V_{RNG3} of the voltage to be generated at the setting terminal SR, based on the comparison result obtained by the comparator 130. For example, when the comparison result obtained by the comparator 130 indicates that the terminal voltage V_{SR2} falls outside the range V_{RNG3} of the voltage to be generated at the setting terminal SR, the constant current circuit 400 switches the magnitude of the constant current I_{CON2} so that the terminal voltage V_{SR2} falls within the voltage range V_{RNG3}.

The constant current circuit 400 according to this embodiment may switch the magnitude of the constant current I_{CON2} so that the terminal voltage V_{SR2} falls within the range V_{RNG3} of the voltage to be generated, when the terminal voltage V_{SR2} falls outside the range V_{RNG3} of the voltage to be generated, based on the comparison result obtained by the comparator 130 when the upper or lower limit reference voltage V_{REF1} of the range V_{RNG3} of the voltage to be generated is generated.

For example, the constant current circuit 400 may increase the constant current I_{CON2} when the comparison result obtained by the comparator 130 indicates that the terminal voltage V_{SR2} is smaller than the lower limit voltage V_{MIN3}. The constant current circuit 400 may also decrease the constant current I_{CON2} when the comparison result obtained by the comparator 130 indicates that the terminal voltage V_{SR2} is larger than the upper limit voltage V_{MAX3}.

Based on the comparison result obtained by the comparator 130, the constant current circuit 400 may switch the magnitude of the constant current I_{CON2} so that the terminal voltage V_{SR2} falls within the range V_{RNG3} of the voltage to be generated, with the reference voltage V_{REF1} fixed to the upper or lower limit voltage of the range V_{RNG3} of the voltage to be generated. For example, the constant current circuit 400 may switch the magnitude of the constant current I_{CON2} so that the terminal voltage V_{SR2} is smaller than the upper limit voltage V_{MAX3}, with the reference voltage V_{REF1} fixed to the upper limit voltage V_{MAX3} of the range V_{RNG3} of the voltage to be generated.

For example, in the case of the pull-down type, when the reference voltage V_{REF1} is the upper limit voltage V_{MAX3}, the comparison result obtained by the comparator 130 indicates that the terminal voltage V_{SR2} is larger than the reference voltage V_{REF1}. In this case, the constant current circuit 400 may decrease the constant current I_{CON2} until the terminal voltage V_{SR2} becomes smaller than the reference voltage V_{REF1}, with the reference voltage V_{REF1} fixed at the upper limit voltage V_{MAX3}.

Alternatively, in the case of the pull-down type, when the reference voltage V_{REF1} is the lower limit voltage V_{MIN3}, the comparison result obtained by the comparator 130 indicates that the terminal voltage V_{SR2} is smaller than the reference voltage V_{REF1}. In this case, the constant current circuit 400 may increase the constant current I_{CON2} until the terminal voltage V_{SR2} becomes larger than the reference voltage V_{REF1}, with the reference voltage V_{REF1} fixed at the lower limit voltage V_{MIN3}.

The reference voltage circuit 120 according to this embodiment may generate a reference voltage V_{REF1} that is the upper or lower limit of the range V_{RNG3} of the voltage to be generated. Specifically, the reference voltage circuit 120 may generate the lower limit voltage V_{MIN3} or the upper limit voltage V_{MAX3} as the reference voltage V_{REF1}.

In addition to the lower limit voltage V_{MIN3} and the upper limit voltage V_{MAX3}, the reference voltage circuit 120 may generate various voltages for specifying the terminal voltage V_{SR2}. For example, in the case of the pull-down type, the reference voltage circuit 120 may generate, as the reference voltage V_{REF1}, a first middle voltage V_{DMID1} that satisfies a relationship of V_{D111}<V_{DMID1}<V_{D121}, a second middle voltage V_{DMID2} that satisfies a relationship of V_{D121}<V_{DMID2}<V_{D131}, and a third middle voltage V_{DMID3} that satisfies a relationship of V_{D131}<V_{DMID3}<V_{D141}.

In the case of the pull-up type, the reference voltage circuit 120 may generate, as the reference voltage V_{REF1}, a first middle voltage V_{UMID1} that satisfies a relationship of V_{U141}<V_{UMID1}<V_{U131}, a second middle voltage V_{UMID2} that satisfies a relationship of V_{U131}<V_{UMID2}<V_{U121}, and a third middle voltage V_{UMID3} that satisfies a relationship of V_{U121}<V_{UMID3}<V_{U111}.

The reference voltage circuit 120 according to this embodiment may sequentially switch the magnitude of the reference voltage V_{REF1} based on the comparison result obtained by the comparator 130. For example, the reference voltage circuit 120 may sequentially increase the magnitude of the reference voltage V_{REF1} from V_{MIN3} based on the comparison result obtained by the comparator 130. Alternatively, the reference voltage circuit 120 may sequentially decrease the magnitude of the reference voltage V_{REF1} from V_{MAX3} based on the comparison result obtained by the comparator 130.

The reference voltage circuit 120 may sequentially switch the magnitude of the reference voltage V_{REF1} after the magnitude of the constant current I_{CON2} is switched so that the terminal voltage V_{SR1} falls within the range V_{RNG3} of the voltage to be generated. This makes it possible to efficiently specify the set value.

In the case of the pull-down type, the control circuit 440 according to this embodiment refers to the table 441 to determine the operation to be performed by the DC/DC converter 442, and cause the DC/DC converter 442 to perform the determined operation. Specifically, the control circuit 440 determines the magnitude of the constant current I_{CON2} and specifies the terminal voltage V_{SR2} when a current corresponding to the determined constant current I_{CON2} flows through the set resistor R_{SET}. The control circuit 440 determines the operation to be performed by the DC/DC converter 442 to be an operation assigned to the set value associated with the constant current I_{CON2} having the determined current value and the specified terminal voltage V_{SR2}. In the case of the pull-up type, the control circuit 440 may refer to a table (not shown) for the pull-up type to determine the operation to be performed by the DC/DC converter 442.

The control circuit 440 according to this embodiment determines the operation to be performed by the DC/DC converter 442, based on the constant current I_{CON2} generated by the constant current circuit 400 and the terminal voltage V_{SR2} when the terminal voltage V_{SR2} falls within the range V_{RNG3} of the voltage to be generated.

The control circuit 440 according to this embodiment may specify the terminal voltage V_{SR2} based on the comparison result obtained by the comparator 130 in response to the sequential switching of the magnitude of the reference voltage V_{REF1}, and may cause the DC/DC converter 442 to perform an operation associated with the specified terminal voltage V_{SR2}. For example, in the case of the pull-down type, when the current value of the constant current I_{CON2} is I₁, the comparison result obtained by the comparator 130 indicates that the terminal voltage V_{SR2} is larger than the first middle voltage V_{DMID1} and smaller than the second middle voltage V_{DMID2}. In this case, the control circuit 440 specifies the terminal voltage V_{SR2} as the voltage V_{D121}, and causes the DC/DC converter 442 to perform an operation associated with the voltage V_{D121}, that is, an operation assigned to the set value 2.

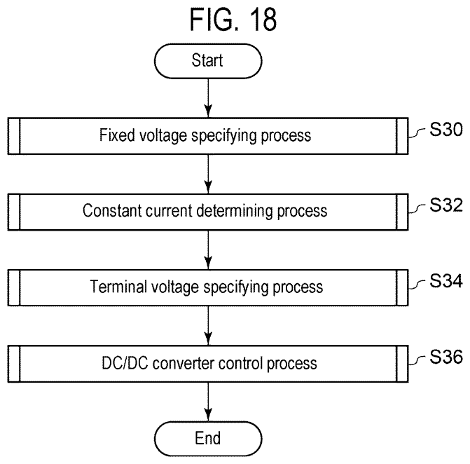

FIG. 18 is a flowchart showing an example of the operation of the semiconductor device 40 according to the fourth embodiment. A flow of the operation of the semiconductor device 40 will be described below with reference to the flowchart shown in FIG. 18.

First, the semiconductor device 40 executes a fixed voltage specifying process (S30). This fixed voltage specifying process is substantially the same as the fixed voltage specifying process (S10) according to the above-described embodiment, and therefore descriptions thereof will be omitted here.

Next, the semiconductor device 40 executes a constant current determining process (S32). The constant current determining process is a process of determining the magnitude of the constant current I_{CON2} so that the terminal voltage V_{SR2} falls within the range V_{RNG3} of the voltage to be generated.

Next, the semiconductor device 40 executes a terminal voltage specifying process (S34). This terminal voltage specifying process is substantially the same as the terminal voltage specifying process (S12) according to the above-described embodiment, and therefore descriptions thereof will be omitted here.

Next, the semiconductor device 40 executes a DC/DC converter control process (S36). This DC/DC converter control process is a process of causing the DC/DC converter 442 to perform an operation associated with the fixed voltage specified in S30 at one end of the set resistor R_{SET}, the constant current I_{CON2} determined in S32, and the terminal voltage V_{SR2} specified in S34. After the DC/DC converter control process is executed, the process shown in FIG. 18 ends.

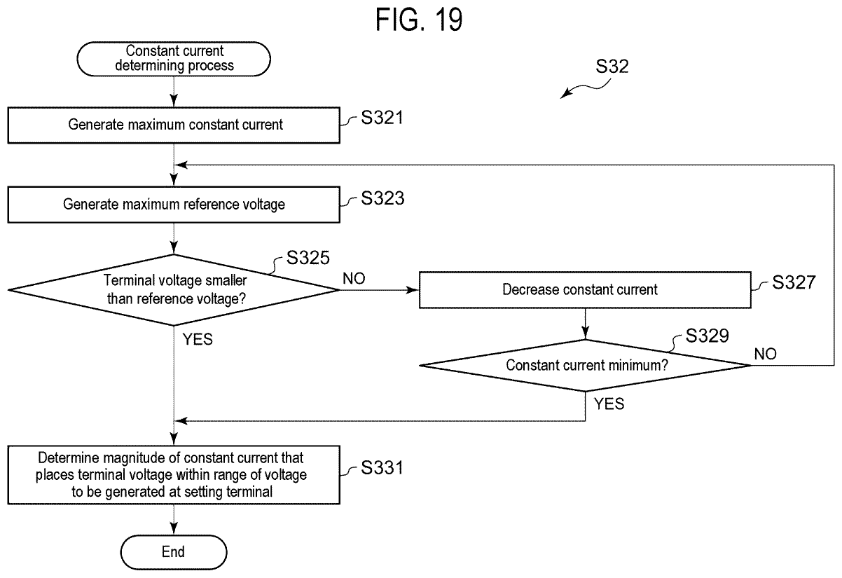

FIG. 19 is a flowchart showing an example of the constant current determining process (S32) according to the fourth embodiment. Here, an example of the pull-down type constant current determining process will be described. A flow of the constant current determining process will be described below with reference to the flowchart shown in FIG. 19.

First, the constant current circuit 400 generates a maximum constant current I_{CON2} (S321). The constant current circuit 100 may generate the constant current I_{CON2} having the current value I₁. Next, the reference voltage circuit 120 generates a maximum reference voltage V_{REF1} (S323). The maximum reference voltage V_{REF1} in S323 may be the upper limit voltage V_{MAX3} of the range V_{RNG3} of the voltage to be generated.

Next, the comparator 130 determines whether or not the terminal voltage V_{SR2} is smaller than the reference voltage V_{REF1} (S325). When it is determined that the terminal voltage V_{SR2} is smaller than the reference voltage V_{REF1} (S325: YES), the process proceeds to S331. On the other hand, when it is determined that the terminal voltage V_{SR2} is equal to or larger than the reference voltage V_{REF1} (S325: NO), the process proceeds to S327.

When it is determined in S325 that the terminal voltage V_{SR2} is equal to or larger than the reference voltage V_{REF1}, the control circuit 440 decreases the constant current I_{CON2} (S327). When the current value of the constant current I_{CON2} is I₁, the control circuit 440 may decrease the current value of the constant current I_{CON2} to I₂, and when the current value of the constant current I_{CON2} is I₂, the control circuit 440 may decrease the current value of the constant current I_{CON2} to I₃.

Next, the control circuit 440 determines whether or not the constant current I_{CON2} is minimum (S329). The control circuit 440 may determine that the constant current I_{CON2} is minimum when the current value of the constant current I_{CON2} is I₃, and may determine that the constant current I_{CON2} is not minimum when the current value of the constant current I_{CON2} is I₁ or I₂. When it is determined that the constant current I_{CON2} is minimum (S329: YES), the process proceeds to S331. On the other hand, when it is determined that the constant current I_{CON2} is not minimum (S109: NO), the process returns to S323.

When it is determined in S325 that the terminal voltage V_{SR2} is smaller than the reference voltage V_{REF1}, or when it is determined in S329 that the constant current I_{CON2} is minimum, the control circuit 440 determines the magnitude of the constant current I_{CON2} that places the terminal voltage V_{SR2} within the range V_{RNG3} of the voltage to be generated at the setting terminal SR (S331). The control circuit 440 according to this embodiment determines the magnitude of the constant current I_{CON2} generated in the process immediately before S331, among the current values I₁ to I₃, to be the magnitude of the constant current I_{CON2} that places the terminal voltage V_{SR2} within the range V_{RNG3} of the voltage to be generated. When S331 ends, the constant current determining process ends.

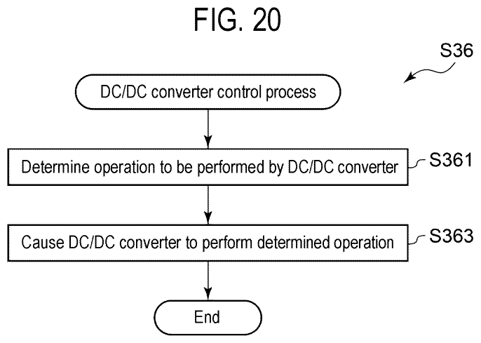

FIG. 20 is a flowchart showing an example of the DC/DC converter control process (S36) according to the fourth embodiment. A flow of the DC/DC converter control process will be described below with reference to the flowchart shown in FIG. 20.

First, the control circuit 440 determines an operation to be performed by the DC/DC converter 442 (S361). The control circuit 440 determines the operation to be performed by the DC/DC converter 442 to be an operation associated with the fixed voltage specified in S30 at one end of the set resistor R_{SET}, the constant current I_{CON2} determined in S32, and the terminal voltage V_{SR2} specified in S34. For example, when the fixed voltage at one end of the set resistor R_{SET} is specified as the ground voltage, the constant current I_{CON2} is determined as the current having the current value I₁, and the terminal voltage V_{SR2} is specified as the voltage V_{D121}, the control circuit 440 may determine the operation to be performed by the DC/DC converter 442 to be an operation assigned to the set value 2.

Next, the control circuit 440 causes the DC/DC converter 442 to perform the operation determined in S361 (S363). When the DC/DC converter 442 performs the determined operation, the DC/DC converter control process ends.

### First Modification

In the second embodiment, an example has been described in which the multiplexer 236 is used to select one of the two comparison signals S_{CMP21} and S_{CMP22}. Without being limited thereto, the control circuit 240 may be configured to select one of the comparison signals S_{CMP21} and S_{CMP22} without using the multiplexer 236.

### Second Modification

In the fourth embodiment, an example has been described in which the reference voltage circuit 120 and the comparator 130 are used to specify the terminal voltage V_{SR2}. Without being limited thereto, an A/D converter that converts the terminal voltage V_{SR2} into a digital signal may be provided instead of the reference voltage circuit 120 and the comparator 130. In this case, the control circuit may determine the operation to be performed by the DC/DC converter 442 based on the digital signal generated by the A/D converter.

Specifically, the constant current circuit 400 switches the magnitude of the constant current I_{CON2} based on the digital signal generated by the A/D converter so that the terminal voltage V_{SR2} falls within the range of the voltage to be generated. The control circuit specifies the terminal voltage V_{SR2} based on the digital signal generated by the A/D converter, with the magnitude of the constant current I_{CON2} fixed so that the terminal voltage V_{SR2} falls within the range of the voltage to be generated. The control circuit causes the DC/DC converter 442 to perform an operation associated with the specified terminal voltage V_{SR2}.

### Third Modification

In the fourth embodiment, an example has been described in which the magnitude of the constant current I_{CON2} is determined by fixing the reference voltage V_{REF1} to V_{MAX3} and decreasing the constant current I_{CON2} until the terminal voltage V_{SR2} becomes smaller than the reference voltage V_{REF1} in the constant current determining process (S32). Without being limited thereto, the magnitude of the constant current I_{CON2} may be determined by fixing the reference voltage V_{REF1} to V_{MIN3} and increasing the constant current I_{CON2} until the terminal voltage V_{SR2} becomes larger than the reference voltage V_{REF1}.

### Fourth Modification

In the above-described embodiments, an example has been described in which the operating circuit is a DC/DC converter. Without being limited thereto, the operating circuit may be a circuit that may realize various functions.

### Fifth Modification

The processes described using the flowcharts in the above-described embodiments do not necessarily have to be performed in the aforementioned order. If necessary, a plurality of operations may be performed in a different order, or may be performed in parallel.

### Supplements

The embodiments according to the present disclosure have been described using specific terms, but this description is merely an example to aid understanding and does not limit the scope of the present disclosure or the claims, and the scope of the present disclosure is defined by the claims. Furthermore, not only the above-described embodiments, but also embodiments, examples, and modifications not described herein are included in the scope of the present invention. It is also possible to combine one or more elements of one embodiment with one or more elements of another embodiment.

### Supplementary Notes

The technique disclosed in the present disclosure may be understood in one aspect as follows.

### Item 1

A semiconductor device comprising:
a constant current circuit configured to generate a constant current; and
an operating circuit configured to perform an operation associated with a fixed voltage at a first end of a set resistor and a voltage at a second end of the set resistor through which a current corresponding to the constant current flows,
wherein the voltage at the second end of the set resistor is a voltage corresponding to the current flowing through the set resistor, and
different operations of the operating circuit are associated with different fixed voltages at the first end of the set resistor.

### Item 2

In the semiconductor device of Item 1 above, voltages at second ends of a plurality of set resistors having different magnitudes are associated with the different fixed voltages at the first end of the set resistor, and
different operations of the operating circuit are associated with the voltages at the second ends of the plurality of set resistors associated with the fixed voltage at the first end of the set resistor.

### Item 3

The semiconductor device of Item 1 or 2 above further includes:
a direction control circuit configured to control a direction of the current flowing through the set resistor, that corresponds to the constant current,
wherein the fixed voltage at the first end of the set resistor is a first fixed voltage or a second fixed voltage larger than the first fixed voltage, and
wherein the direction control circuit directs the current flowing through the set resistor from the second end to the first end of the set resistor when the fixed voltage at the first end of the set resistor is the first fixed voltage, and directs the current flowing through the set resistor from the first end to the second end of the set resistor when the fixed voltage at the first end of the set resistor is the second fixed voltage.

### Item 4

The semiconductor device of Item 3 above further includes:
a reference voltage circuit configured to generate a reference voltage and to be capable of switching a magnitude of the reference voltage;
a comparison circuit including a comparator configured to compare the reference voltage with the voltage at the second end of the set resistor; and
a control circuit configured to control the operation of the operating circuit, wherein the control circuit determines the operation to be performed by the operating circuit based on a comparison result obtained by the comparator.

### Item 5

In the semiconductor device of Item 4 above, the control circuit specifies the fixed voltage at the first end of the set resistor based on a comparison result obtained by the comparator when no current flows through the set resistor, specifies the voltage at the second end of the set resistor based on a comparison result obtained by the comparator when the current corresponding to the constant current flows through the set resistor, and causes the operating circuit to perform an operation associated with the specified fixed voltage at the first end of the set resistor and the specified voltage at the second end of the set resistor.

### Item 6

In the semiconductor device of Item 5 above, the reference voltage circuit sequentially switches the magnitude of the reference voltage based on the comparison result obtained by the comparator, and
the control circuit specifies the voltage at the second end of the set resistor based on the comparison result obtained by the comparator, which corresponds to the sequential switching of the magnitude of the reference voltage, and causes the operating circuit to perform an operation associated with the specified voltage at the second end of the set resistor.

### Item 7

In the semiconductor device of any one of Items 4 to 6 above, the reference voltage circuit generates the reference voltage by dividing a voltage difference between the first fixed voltage and the second fixed voltage, and switches the magnitude of the reference voltage by switching a voltage division ratio.

### Item 8

In the semiconductor device of Item 4 above, the comparison circuit includes:
a first comparator configured to operate normally when an input voltage falls within a first voltage range; and
a second comparator configured to operate normally when the input voltage falls within a second voltage range,
wherein a lower limit voltage in the first voltage range is equal to or smaller than the first fixed voltage,
an upper limit voltage in the first voltage range is smaller than the second fixed voltage,
a lower limit voltage in the second voltage range is larger than the first fixed voltage,
an upper limit voltage in the second voltage range is equal to or larger than the second fixed voltage,
each of the first comparator and the second comparator compares the reference voltage with the voltage at the second end of the set resistor, and
the control circuit specifies the voltage at the second end of the set resistor based on a comparison result obtained by the first comparator when the fixed voltage at the first end of the set resistor is the first fixed voltage, specifies the voltage at the second end of the set resistor based on a comparison result obtained by the second comparator when the fixed voltage at the first end of the set resistor is the second fixed voltage, and causes the operating circuit to perform an operation associated with the specified voltage at the second end of the set resistor.

### Item 9

The semiconductor device of any one of Items 3 to 8 above further includes:
a first current mirror circuit configured to copy the constant current,
wherein the direction control circuit includes a second current mirror circuit configured to copy a current generated by the first current mirror circuit copying the constant current, and a switching circuit configured to be capable of switching the current flowing through the set resistor between the current generated by the first current mirror circuit and a current generated by the second current mirror circuit, and
the switching circuit directs the current flowing through the set resistor from the second end to the first end of the set resistor by passing the current generated by the first current mirror circuit configured to copy the constant current through the set resistor, and directs the current flowing through the set resistor from the first end to the second end of the set resistor by passing the current generated by the second current mirror circuit configured to copy the current generated by the first current mirror circuit through the set resistor.

### Item 10

In the semiconductor device of Item 9 above, the first fixed voltage is a ground voltage,
the second fixed voltage is a power supply voltage,
the first current mirror circuit is composed of two P-channel MOS transistors, and
sources of the two P-channel MOS transistors are connected to an application terminal of the power supply voltage.

### Item 11

In the semiconductor device of Item 10 above, the constant current circuit includes:
a voltage divider circuit configured to divide the power supply voltage;
an operational amplifier;
a MOS transistor; and
a resistor provided between the MOS transistor and a ground,
wherein the MOS transistor is provided so as to receive an output signal of the operational amplifier at a gate of the MOS transistor and allow the constant current to flow through the MOS transistor,
a voltage generated by the voltage divider circuit configured to divide the power supply voltage is input to a non-inverting input terminal of the operational amplifier, and
the voltage at the first end of the set resistor on a side of the MOS transistor is input to an inverting input terminal of the operational amplifier.

### Item 12

The semiconductor device of Item 3 above further includes:
an A/D converter configured to convert the voltage at the second end of the set resistor into a digital signal; and
a control circuit configured to determine an operation to be performed by the operating circuit based on the digital signal,
wherein the control circuit specifies the fixed voltage at the first end of the set resistor based on the digital signal when no current flows through the set resistor, specifies the voltage at the second end of the set resistor based on the digital signal when the current corresponding to the constant current flows through the set resistor, and causes the operating circuit to perform an operation associated with the specified voltage at the second end of the set resistor.

### Item 13

In the semiconductor device of Item 1 above, the constant current circuit is configured to be capable of switching a magnitude of the constant current,
the operating circuit performs an operation associated with the constant current generated by the constant current circuit in addition to the fixed voltage at the first end of the set resistor and the voltage at the second end of the set resistor through which the current corresponding to the constant current flows, and
different operations of the operating circuit are associated with constant currents of different magnitudes, which are generated by the constant current circuit.

### Item 14

In the semiconductor device of Item 13 above, voltages at second ends of a plurality of set resistors having different magnitudes are associated with the constant current generated by the constant current circuit, and
different operations are associated with the voltages at the second ends of the plurality of set resistors associated with the constant current.

### Item 15

The semiconductor device of Item 14 above further includes:
a control circuit configured to control the operation of the operating circuit,
wherein the constant current circuit switches the magnitude of the constant current so that the voltage at the first end of the set resistor falls within a range of a voltage to be generated at the second end of the set resistor when the voltage at the first end of the set resistor falls outside the range of the voltage to be generated,
the control circuit determines the operation to be performed by the operating circuit based on the constant current generated by the constant current circuit and the voltage at the second end of the set resistor when the voltage at the second end of the set resistor falls within the range of the voltage to be generated, and
the operating circuit performs the operation determined by the control circuit.

### Item 16

The semiconductor device of Item 15 above further includes:
a reference voltage circuit configured to generate a reference voltage and to be capable of switching the magnitude of the reference voltage; and
a comparator configured to compare the reference voltage with the voltage at the second end of the set resistor, and
wherein the control circuit determines the operation to be performed by the operating circuit based on a comparison result obtained by the comparator.

### Item 17

In the semiconductor device of Item 16 above, the reference voltage circuit generates an upper limit or lower limit voltage in the range of the voltage to be generated, as the reference voltage, and
the constant current circuit switches the magnitude of the constant current so that the voltage at the first end of the set resistor falls within the range of the voltage to be generated, when the voltage at the second end of the set resistor falls outside the range of the voltage to be generated, based on the comparison result obtained by the comparator when the upper or lower limit reference voltage is generated.

### Item 18

In the semiconductor device of Item 17 above, the constant current circuit switches the magnitude of the constant current based on the comparison result obtained by the comparator so that the voltage at the second end of the set resistor falls within the range of the voltage to be generated,
the reference voltage circuit sequentially switches the magnitude of the reference voltage based on the comparison result obtained by the comparator, and
the control circuit specifies the voltage at the second end of the set resistor based on the comparison result obtained by the comparator in response to the sequential switching of the magnitude of the reference voltage, and causes the operating circuit to perform an operation associated with the specified voltage at the second end of the set resistor.

### Item 19

In the semiconductor device of Item 17 above, the constant current circuit switches the magnitude of the constant current based on the comparison result obtained by the comparator so that the voltage at the second end of the set resistor falls within the range of the voltage to be generated, with the reference voltage fixed to the upper or lower limit voltage,
the reference voltage circuit sequentially switches the magnitude of the reference voltage after switching the magnitude of the constant current so that the voltage at the second end of the set resistor falls within the range of the voltage to be generated, and
the control circuit specifies the voltage at the second end of the set resistor based on the comparison result obtained by the comparator in response to the sequential switching of the magnitude of the reference voltage, and causes the operating circuit to perform an operation associated with the specified voltage at the second end of the set resistor.

### Item 20

In the semiconductor device of any one of Items 16 to 19 above, the reference voltage circuit generates the reference voltage by dividing a power supply voltage, and switches the magnitude of the reference voltage by switching a voltage division ratio.

### Item 21

The semiconductor device of Item 15 above further includes:
an A/D converter configured to convert the voltage at the second end of the set resistor into a digital signal,
wherein the control circuit determines an operation to be performed by the operating circuit based on the digital signal.

### Item 22

In the semiconductor device of Item 21 above, the constant current circuit switches the magnitude of the constant current based on the digital signal generated by the A/D converter so that the voltage at the second end of the set resistor falls within the range of the voltage to be generated, and
the control circuit specifies the voltage at the second end of the set resistor based on the digital signal generated by the A/D converter, with the magnitude of the constant current fixed so that the voltage at the second end of the set resistor falls within the range of the voltage to be generated, and causes the operating circuit to perform an operation associated with the specified voltage at the second end of the set resistor.

### Item 23

In the semiconductor device of any one of Item 13 to 22 above, the constant current circuit generates a first constant current when the resistance value of the set resistor is a first resistance value, and generates a second constant current having a magnitude of 1/N times the first constant current when the resistance value of the set resistor is a second resistance value that is N times the first resistance value (N is a number larger than 1).

### Item 24

In the semiconductor device of any one of Items 13 to 23 above, the constant current circuit includes a voltage divider circuit configured to divide a power supply voltage, an operational amplifier, a MOS transistor, and a resistor provided between the MOS transistor and a ground,
the MOS transistor is provided so as to receive an output signal of the operational amplifier at a gate of the MOS transistor and allow the constant current to flow through the MOS transistor,
a voltage generated by the voltage divider circuit configured to divide the power supply voltage is input to a non-inverting input terminal of the operational amplifier, and
the voltage at the first end of the set resistor on a side of the MOS transistor is input to an inverting input terminal of the operational amplifier.

### Item 25

The semiconductor device of any one of Items 13 to 24 above further includes:
a current mirror circuit configured to copy the constant current generated by the constant current circuit,
wherein a current corresponding to the constant current copied by the current mirror circuit flows through the set resistor.

### Item 26

In the semiconductor device of any one of Items 13 to 25 above, the operating circuit is a DC/DC converter.

What is claimed is:

1. A semiconductor device comprising:
a constant current circuit configured to generate a constant current; and
an operating circuit configured to perform an operation associated with a fixed voltage at a first end of a set resistor and a voltage at a second end of the set resistor through which a current corresponding to the constant current flows,
wherein the voltage at the second end of the set resistor is a voltage corresponding to the current flowing through the set resistor, and
wherein different operations of the operating circuit are associated with different fixed voltages at the first end of the set resistor.

2. The semiconductor device of claim 1, wherein voltages at second ends of a plurality of set resistors having different magnitudes are associated with the different fixed voltages at the first end of the set resistor, and
wherein the different operations of the operating circuit are associated with the voltages at the second ends of the plurality of set resistors associated with the fixed voltage at the first end of the set resistor.

3. The semiconductor device of claim 1, further comprising:
a direction control circuit configured to control a direction of the current flowing through the set resistor, that corresponds to the constant current,
wherein the fixed voltage at the first end of the set resistor is a first fixed voltage or a second fixed voltage larger than the first fixed voltage, and
wherein the direction control circuit directs the current flowing through the set resistor from the second end to the first end of the set resistor when the fixed voltage at the first end of the set resistor is the first fixed voltage, and directs the current flowing through the set resistor from the first end to the second end of the set resistor when the fixed voltage at the first end of the set resistor is the second fixed voltage.

4. The semiconductor device of claim 3, further comprising:
a reference voltage circuit configured to generate a reference voltage and to be capable of switching a magnitude of the reference voltage;
a comparison circuit including a comparator configured to compare the reference voltage with the voltage at the second end of the set resistor; and
a control circuit configured to control the operation of the operating circuit,
wherein the control circuit determines the operation to be performed by the operating circuit based on a comparison result obtained by the comparator.

5. The semiconductor device of claim 4, wherein the control circuit specifies the fixed voltage at the first end of the set resistor based on the comparison result obtained by the comparator when no current flows through the set resistor, specifies the voltage at the second end of the set resistor based on the comparison result obtained by the comparator when the current corresponding to the constant current flows through the set resistor, and causes the operating circuit to perform an operation associated with the specified fixed voltage at the first end of the set resistor and the specified voltage at the second end of the set resistor.

6. The semiconductor device of claim 5, wherein the reference voltage circuit sequentially switches the magnitude of the reference voltage based on the comparison result obtained by the comparator, and
wherein the control circuit specifies the voltage at the second end of the set resistor based on the comparison result obtained by the comparator, which corresponds to the sequential switching of the magnitude of the reference voltage, and causes the operating circuit to perform an operation associated with the specified voltage at the second end of the set resistor.

7. The semiconductor device of claim 4, wherein the reference voltage circuit generates the reference voltage by dividing a voltage difference between the first fixed voltage and the second fixed voltage, and switches the magnitude of the reference voltage by switching a voltage division ratio.

8. The semiconductor device of claim 4, wherein the comparison circuit includes:
a first comparator configured to operate normally when an input voltage falls within a first voltage range; and
a second comparator configured to operate normally when the input voltage falls within a second voltage range,
wherein a lower limit voltage in the first voltage range is equal to or smaller than the first fixed voltage,
wherein an upper limit voltage in the first voltage range is smaller than the second fixed voltage,
wherein a lower limit voltage in the second voltage range is larger than the first fixed voltage,
wherein an upper limit voltage in the second voltage range is equal to or larger than the second fixed voltage,
wherein each of the first comparator and the second comparator compares the reference voltage with the voltage at the second end of the set resistor, and
wherein the control circuit specifies the voltage at the second end of the set resistor based on the comparison result obtained by the first comparator when the fixed voltage at the first end of the set resistor is the first fixed voltage, specifies the voltage at the second end of the set resistor based on the comparison result obtained by the second comparator when the fixed voltage at the first end of the set resistor is the second fixed voltage, and causes the operating circuit to perform an operation associated with the specified voltage at the second end of the set resistor.

9. The semiconductor device of claim 3, further comprising:
a first current mirror circuit configured to copy the constant current,
wherein the direction control circuit includes:
a second current mirror circuit configured to copy a current generated by the first current mirror circuit copying the constant current; and
a switching circuit configured to be capable of switching the current flowing through the set resistor between the current generated by the first current mirror circuit and a current generated by the second current mirror circuit, and
wherein the switching circuit directs the current flowing through the set resistor from the second end to the first end of the set resistor by passing the current generated by the first current mirror circuit configured to copy the constant current through the set resistor, and directs the current flowing through the set resistor from the first end to the second end of the set resistor by passing the current generated by the second current mirror circuit configured to copy the current generated by the first current mirror circuit through the set resistor.

10. The semiconductor device of claim 9, wherein the first fixed voltage is a ground voltage,
wherein the second fixed voltage is a power supply voltage,
wherein the first current mirror circuit is composed of two P-channel MOS transistors, and
wherein sources of the two P-channel MOS transistors are connected to an application terminal of the power supply voltage.

11. The semiconductor device of claim 10, wherein the constant current circuit includes:
a voltage divider circuit configured to divide the power supply voltage;
an operational amplifier;
a MOS transistor; and
a resistor provided between the MOS transistor and a ground,
wherein the MOS transistor is provided so as to receive an output signal of the operational amplifier at a gate of the MOS transistor and allow the constant current to flow through the MOS transistor,
wherein a voltage generated by the voltage divider circuit configured to divide the power supply voltage is input to a non-inverting input terminal of the operational amplifier, and
wherein the voltage at the first end of the set resistor on a side of the MOS transistor is input to an inverting input terminal of the operational amplifier.

12. The semiconductor device of claim 3, further comprising:
an A/D converter configured to convert the voltage at the second end of the set resistor into a digital signal; and
a control circuit configured to determine an operation to be performed by the operating circuit based on the digital signal,
wherein the control circuit specifies the fixed voltage at the first end of the set resistor based on the digital signal when no current flows through the set resistor, specifies the voltage at the second end of the set resistor based on the digital signal when the current corresponding to the constant current flows through the set resistor, and causes the operating circuit to perform an operation associated with the specified voltage at the second end of the set resistor.

13. The semiconductor device of claim 1, wherein the constant current circuit is configured to be capable of switching a magnitude of the constant current,
wherein the operating circuit performs an operation associated with the constant current generated by the constant current circuit in addition to the fixed voltage at the first end of the set resistor and the voltage at the second end of the set resistor through which the current corresponding to the constant current flows, and
wherein different operations of the operating circuit are associated with constant currents of different magnitudes, that are generated by the constant current circuit.

14. The semiconductor device of claim 13, wherein voltages at second ends of a plurality of set resistors having different magnitudes are associated with the constant current generated by the constant current circuit, and
wherein different operations are associated with the voltages at the second ends of the plurality of set resistors associated with the constant current.

15. The semiconductor device of claim 14, further comprising:
a control circuit configured to control the operation of the operating circuit,
wherein the constant current circuit switches the magnitude of the constant current so that the voltage at the first end of the set resistor falls within a range of a voltage to be generated at the second end of the set resistor when the voltage at the first end of the set resistor falls outside the range of the voltage to be generated,
wherein the control circuit determines the operation to be performed by the operating circuit based on the constant current generated by the constant current circuit and the voltage at the second end of the set resistor when the voltage at the second end of the set resistor falls within the range of the voltage to be generated, and
wherein the operating circuit performs the operation determined by the control circuit.

16. The semiconductor device of claim 15, further comprising:
a reference voltage circuit configured to generate a reference voltage and to be capable of switching a magnitude of the reference voltage; and
a comparator configured to compare the reference voltage with the voltage at the second end of the set resistor, and
wherein the control circuit determines the operation to be performed by the operating circuit based on a comparison result obtained by the comparator.

17. The semiconductor device of claim 16, wherein the reference voltage circuit generates an upper limit or lower limit voltage in the range of the voltage to be generated, as the reference voltage, and
wherein the constant current circuit switches the magnitude of the constant current so that the voltage at the first end of the set resistor falls within the range of the voltage to be generated, when the voltage at the second end of the set resistor falls outside the range of the voltage to be generated, based on the comparison result obtained by the comparator when the upper or lower limit reference voltage is generated.

18. The semiconductor device of claim 17, wherein the constant current circuit switches the magnitude of the constant current based on the comparison result obtained by the comparator so that the voltage at the second end of the set resistor falls within the range of the voltage to be generated,
wherein the reference voltage circuit sequentially switches the magnitude of the reference voltage based on the comparison result obtained by the comparator, and
wherein the control circuit specifies the voltage at the second end of the set resistor based on the comparison result obtained by the comparator in response to the sequential switching of the magnitude of the reference voltage, and causes the operating circuit to perform an operation associated with the specified voltage at the second end of the set resistor.

19. The semiconductor device of claim 17, wherein the constant current circuit switches the magnitude of the constant current based on the comparison result obtained by the comparator so that the voltage at the second end of the set resistor falls within the range of the voltage to be generated, with the reference voltage fixed to the upper or lower limit voltage,
wherein the reference voltage circuit sequentially switches the magnitude of the reference voltage after switching the magnitude of the constant current so that the voltage at the second end of the set resistor falls within the range of the voltage to be generated, and
wherein the control circuit specifies the voltage at the second end of the set resistor based on the comparison result obtained by the comparator in response to the sequential switching of the magnitude of the reference voltage, and causes the operating circuit to perform an operation associated with the specified voltage at the second end of the set resistor.

20. The semiconductor device of claim 16, wherein the reference voltage circuit generates the reference voltage by dividing a power supply voltage, and switches the magnitude of the reference voltage by switching a voltage division ratio.

21. The semiconductor device of claim 15, further comprising:
an A/D converter configured to convert the voltage at the second end of the set resistor into a digital signal,
wherein the control circuit determines an operation to be performed by the operating circuit based on the digital signal.

22. The semiconductor device of claim 21, wherein the constant current circuit switches the magnitude of the constant current based on the digital signal generated by the A/D converter so that the voltage at the second end of the set resistor falls within the range of the voltage to be generated, and
wherein the control circuit specifies the voltage at the second end of the set resistor based on the digital signal generated by the A/D converter, with the magnitude of the constant current fixed so that the voltage at the second end of the set resistor falls within the range of the voltage to be generated, and causes the operating circuit to perform an operation associated with the specified voltage at the second end of the set resistor.

23. The semiconductor device of claim 13, wherein the constant current circuit generates a first constant current when the resistance value of the set resistor is a first resistance value, and generates a second constant current having a magnitude of 1/N times the first constant current when the resistance value of the set resistor is a second resistance value that is N times the first resistance value (N is a number larger than 1).

24. The semiconductor device of claim 15, wherein the constant current circuit includes a voltage divider circuit configured to divide a power supply voltage, an operational amplifier, a MOS transistor, and a resistor provided between the MOS transistor and a ground,
wherein the MOS transistor is provided so as to receive an output signal of the operational amplifier at a gate of the MOS transistor and allow the constant current to flow through the MOS transistor,
wherein a voltage generated by the voltage divider circuit configured to divide the power supply voltage is input to a non-inverting input terminal of the operational amplifier, and
wherein the voltage at the first end of the set resistor on a side of the MOS transistor is input to an inverting input terminal of the operational amplifier.

25. The semiconductor device of claim 13, further comprising:
a current mirror circuit configured to copy the constant current generated by the constant current circuit,
wherein a current corresponding to the constant current copied by the current mirror circuit flows through the set resistor.

26. The semiconductor device of claim 1, wherein the operating circuit is a DC/DC converter.
